(19) United States
(12) Patent Application Publication
(10) Pub. No.: US 2016/0027846 A1
(43) Pub. Date: Jan. 28, 2016

(54) THREE-DIMENSIONAL NETWORKS COMPRISING NANOELECTRONICS

(71) Applicant: PRESIDENT AND FELLOW OF HARVARD COLLEGE, Cambridge, MA (US)

(72) Inventors: Charles M. Lieber, Lexington, MA (US); Jia Liu, Somerville, MA (US); Chong Xie, Austin, TX (US); Xiaochuan Dai, Somerville, MA (US)

(21) Appl. No.: 14/782,161

(22) PCT Filed: Apr. 3, 2014
(86) PCT No.: PCT/US2014/032743

§ 371 Date: Oct. 2, 2015

Related U.S. Application Data
(60) Provisional application No. 61/809,220, filed on Apr. 5, 2013.

(51) Int. Cl. H01L 27/28; C08J 9/00; G01N 31/22; H01L 29/06; G01R 31/00; H05K 1/09; H01L 29/786; H05K 1/03; G01B 7/16; C08K 7/00; H01L 29/16

(52) U.S. Cl. CPC H01L 27/281; C08K 7/00; C08J 9/0071; G01N 31/221; H01L 29/0669; H01L 29/16; H05K 1/09; H01L 29/786; H05K 1/038; H05K 1/0393; G01B 7/16; G01R 31/00

(57) ABSTRACT

The present invention generally relates to nanoscale wires and three-dimensional networks or structures comprising nanoscale wires. For example, certain embodiments are directed to three-dimensional structures comprising nanoscale wires. The structures may be porous and define electrical networks wherein the nanoscale wires can be determined or controlled. Other materials, such as inorganic materials, polymers, fabrics, etc., may be disposed within the three-dimensional structure, and in some embodiments, such that the three-dimensional structure is embedded within the material. The nanoscale wires may thus be used, for example, as sensors within the material. Other embodiments of the invention are generally directed to the use of such articles, methods of forming such articles, kits involving such articles, or the like.

### RELATED APPLICATIONS

This application claims the benefit of U.S. Provisional Patent Application Ser. No. 61/809,220, filed Apr. 5, 2013, entitled “Three-Dimensional Networks Comprising Nanoelectronics,” by Lieber, et al., incorporated herein by reference in its entirety.

### GOVERNMENT FUNDING

Research leading to various aspects of the present invention was sponsored, at least in part, by the Department of Defense (National Security Science and Engineering Faculty Fellow), Grant No. N00244-09-1-0078, and by the National Institutes of Health (Director's Pioneer Award), Grant No. DP1GM105379. The U.S. Government has certain rights in the invention.

### FIELD

The present invention generally relates to nanoscale wires and three-dimensional networks or structures comprising nanoscale wires.

### BACKGROUND

Two basic methods have been used to fabricate 3D integrated electronic circuits. The first involves bonding substrates, each containing devices/circuits integrated in 2D, together in a 3D stack. The second exploits bottom-up assembly of nanoelectronic elements in a layer-by-layer manner. However, both methods yield solid or nonporous 3D structures that only allow the top-most layer of electronic elements to be merged directly with a second material and thus precluding integration of all of the electronic elements seamlessly with a host material in 3D. Accordingly, improvements in fabrication techniques are needed.

### SUMMARY

The present invention generally relates to nanoscale wires and three-dimensional networks or structures comprising nanoscale wires. The subject matter of the present invention involves, in some cases, interrelated products, alternative solutions to a particular problem, and/or a plurality of different uses of one or more systems and/or articles.

In one aspect, the present invention is generally directed to an article. The article, in one set of embodiments, comprises an inorganic material comprising a three-dimensional structure comprising nanoscale wires. In another set of embodiments, the article comprises a polymer comprising a three-dimensional structure comprising nanoscale wires, wherein the polymer comprises non-naturally occurring monomers. According to another set of embodiments, the article comprises a fabric comprising a three-dimensional structure comprising nanoscale wires, wherein the polymer comprises non-naturally occurring monomers. In still another set of embodiments, the article comprises rubber comprising a three-dimensional structure comprising nanoscale wires, wherein the polymer comprises non-naturally occurring monomers.

In one set of embodiments, the article comprises a fluidic channel, wherein at least a portion of a wall of the fluidic channel comprises a three-dimensional structure comprising nanoscale wires. The article, according to another set of embodiments, includes a fluidic channel, where at least a portion of a wall of the fluidic channel comprises a curled 2-dimensional electrical network comprising nanoscale wires. The article, in still another set of embodiments, comprises a fluidic channel, where at least a portion of a wall of the channel comprises a 3-dimensional structure having an average pore size of between about 100 micrometers and about 1.5 mm.

In one set of embodiments, the article comprises a fabric comprising nanoscale wires. In some cases, at least some of the nanoscale wires are connectable to an electrical circuit that extends externally of the fabric. In another set of embodiments, the article comprises rubber comprising nanoscale wires. In certain embodiments, at least some of the nanoscale wires are connectable to an electrical circuit that extends externally of the rubber.

The article, in yet another set of embodiments, defines a microfluidic system and comprises nanoscale wires. In some embodiments, at least some of the nanoscale wires are connectable to an electrical circuit that extends externally of the article.

Another aspect of the present invention is generally directed to a method. In one set of embodiments, the method comprises determining a chemical, mechanical, and/or electrical property of an inorganic material at a resolution of at least 1 mm using sensors disposed internally of the inorganic material. The method, in another set of embodiments, includes determining a chemical, mechanical, and/or electrical property of a rubber at a resolution of at least 1 mm using sensors disposed internally of the rubber. According to another set of embodiments, the method includes determining a chemical, mechanical, and/or electrical property of a fabric at a resolution of at least 1 mm using sensors disposed internally of the fabric.

In still another set of embodiments, the method comprises determining a chemical, mechanical, and/or electrical property of a polymeric material at a resolution of less than 1 mm using sensors disposed internally of the polymeric material. In some cases, the polymeric material comprises non-naturally occurring monomers.

The method, in accordance with yet another set of embodiments, includes determining mechanical strain of a material by determining electrical properties of nanoscale wires contained within a three-dimensional network within the material. In another aspect, the present invention encompasses methods of making one or more of the embodiments described herein, for example, three-dimensional networks or structures comprising nanoscale wires. In still another aspect, the present invention encompasses methods of using one or more of the embodiments described herein, for example, three-dimensional networks or structures comprising nanoscale wires. Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIGS. 1A-1C illustrate three-dimensional structures in accordance with one embodiment of the invention;

FIGS. 2A-2H illustrate various three-dimensional structures, in certain embodiments of the invention;

FIGS. 3A-3C illustrate localization of nanowires in a three-dimensional structure, in yet another embodiment of the invention;

FIGS. 4A-4E illustrate chemical sensors in accordance with yet another embodiment of the invention;

FIGS. 5A-5C illustrate strain determination, in still another embodiment of the invention;

FIG. 6 illustrates an electronic network in another embodiment of the invention;

FIGS. 7A-7C illustrate the determination of bending stiffness, in yet another embodiment of the invention;

FIGS. 8A-8B illustrate various schematics for calculations, in another embodiment of the invention;

FIGS. 9A-9C illustrate localization of nanowires in a three-dimensional structure, in another embodiment of the invention; and

FIGS. 10A-10B illustrate calibration of nanowire sensors, in still another embodiment of the invention.

### DETAILED DESCRIPTION

The present invention generally relates to nanoscale wires and three-dimensional networks or structures comprising nanoscale wires. For example, certain embodiments are directed to three-dimensional structures comprising nanoscale wires. The structures may be porous and define electrical networks wherein the nanoscale wires can be determined or controlled. Other materials, such as inorganic materials, polymers, fabrics, etc., may be disposed within the three-dimensional structure, and in some embodiments, such that the three-dimensional structure is embedded within the material. The nanoscale wires may thus be used, for example, as sensors within the material. Other embodiments of the invention are generally directed to the use of such articles, methods of forming such articles, kits involving such articles, or the like.

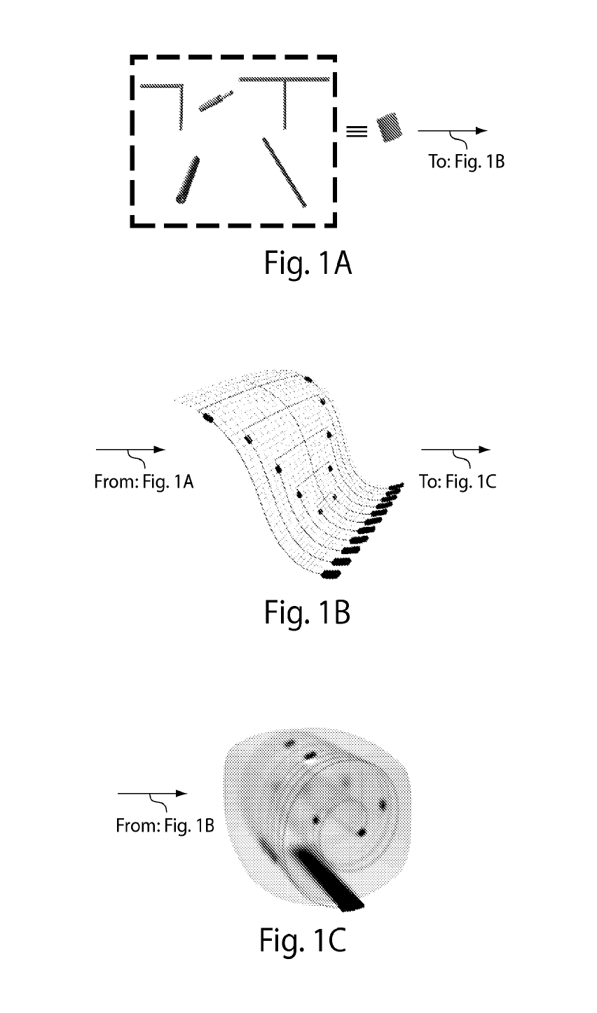

Turning first to FIG. 1, a representative three-dimensional structure is now briefly described in accordance with certain aspects of the invention. Additional details of the components forming the cell scaffold will be discussed in more detail below, including various techniques for fabricating such cell scaffolds. In FIG. 1B, a two-dimensional structure is formed out of various electronic components such as those illustrated schematically in FIG. 1A. For example, the electronic components may include nanoscale wires such as semiconductor nanowires (e.g., comprising silicon). Examples of such nanoscale wires are described in more detail below. The structure may also comprise polymeric materials or constructs, e.g., photoresist polymers such as SU-8.

As fabricated, the two-dimensional structure may contain conductive pathways in electrical communication with some of the nanoscale wires, and in some cases, the conductive pathways can extend externally of the surface of the structure, as is shown at the bottom of FIG. 1B. For example, some of the conductive pathways may be connectable to an external electrical system, such as a computer or a transmitter, e.g., such that physical and/or electrical properties of the nanoscale wires can be determined, and/or such that electrical stimuli can be applied to the nanoscale wires. Thus, the conductive pathways and nanoscale wires may form part of an electrical circuit in some cases.

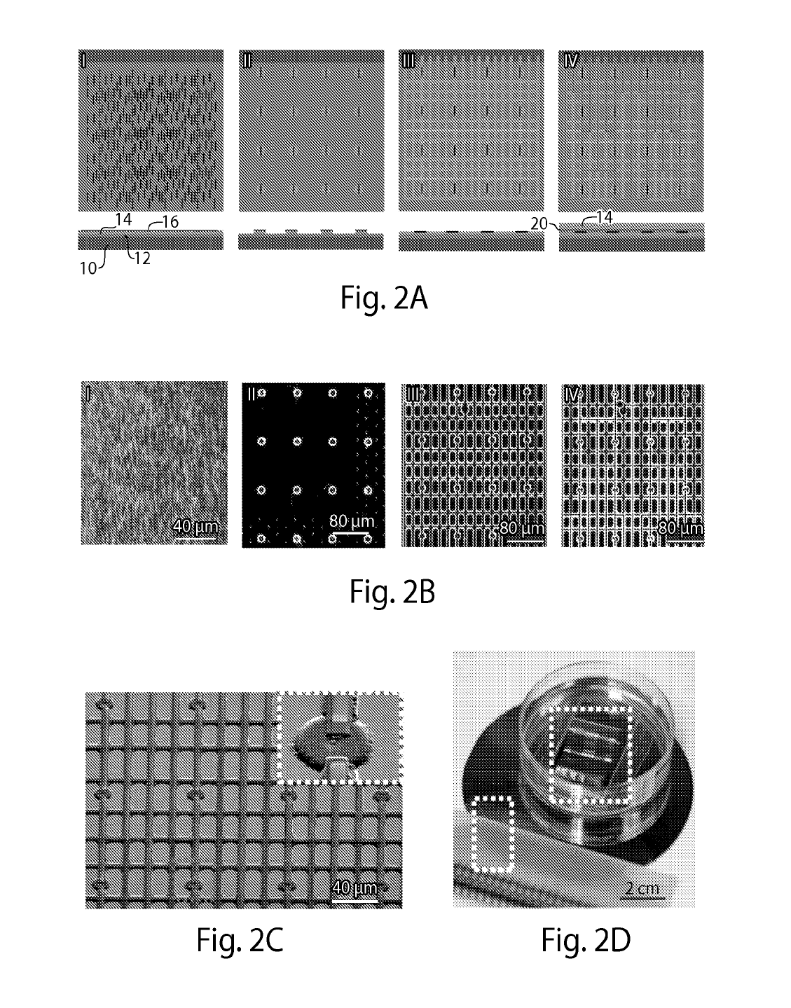

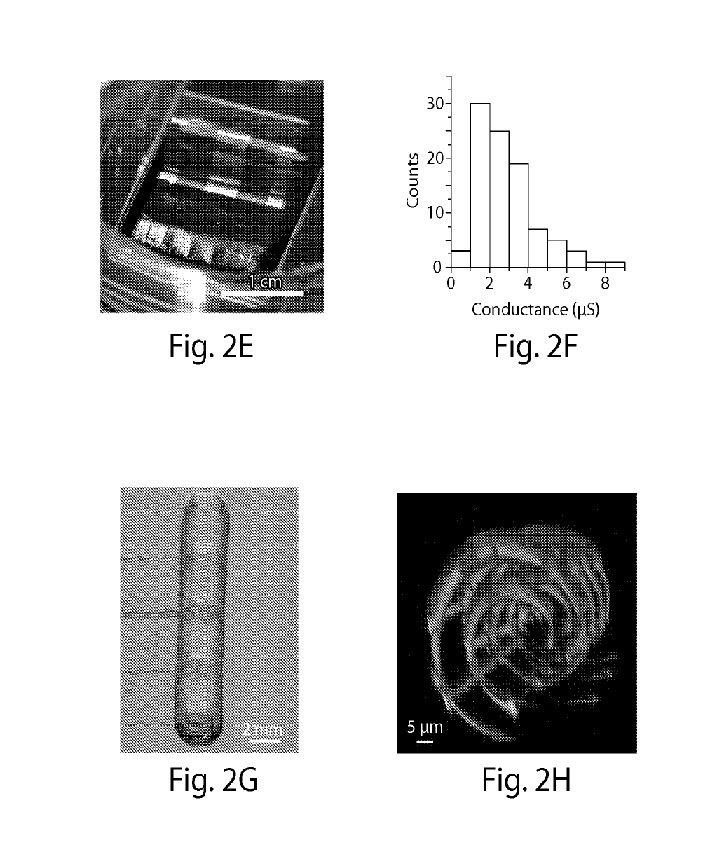

Although the structure in FIG. 1B is generally described as two-dimensional, in reality, it of course has three dimensions, where one dimension is much smaller than the other two. Such an initial two-dimensional structure may be formed using microfabrication techniques such as those described below; for example, photolithographic techniques. In some cases, the structure is initially formed, then removed from a substrate. The substrate may also have holes or pores contained therein, e.g., as is shown in FIG. 2. The two-dimensional substrate may then be manipulated to adopt a 3-dimensional structure, for example, by bending, folding, or rolling the structure, or using other suitable techniques. For example, in FIG. 1C, the two-dimensional structure has been rolled up to form a three-dimensional structure. For instance, in some embodiments, dissimilar metals (e.g., chromium and palladium) can be used to cause the structure to adopt a 3-dimensional structure once released from a substrate. In other embodiments, however, the two-dimensional structure may be formed into a three-dimensional structure using external forces, e.g., mechanically or manually.

In certain embodiments, other materials may be added to the structure, e.g., before or after forming a 3-dimensional structure. In one set of embodiments, the material may be an inorganic material such as a metal. In another set of embodiments, the material may comprise a polymer. The polymer may comprise naturally occurring monomers and/or non-naturally occurring monomers. In one set of embodiments, the polymer comprises a gel, such as polyacrylamide or agarose. In some embodiments, the structure may be rolled into a hollow structure or “tube” or channel, and other materials inserted inside of the tube. As another example, a material may partially or completely surround the structure (e.g., entering through pores or holes within the structure, if present), and in some cases, solidified (e.g., polymerized) such that the three-dimensional structure becomes embedded partially or completely within the material. In some cases, the material may be completely solid, although in other cases, the material need not be solid, e.g., there may be channels, passages, pores, voids, etc. present within the material. In one embodiment, the three-dimensional structure may be embedded within a material such that only one or more electrical connectors extend externally of the material, e.g., for connection of conductive pathways within the three-dimensional structure to an external electrical system, such as a computer or a transmitter.

The above discussion is just a brief summary of some embodiments of the present invention. However, it should be understood that other embodiments are also possible in addition to the ones described above, involving various types of materials, techniques for forming three-dimensional networks or structures comprising nanoscale wires and the like, which will now be discussed in greater detail.

In one aspect, the present invention is generally directed to three-dimensional networks or structures comprising nanoscale wires, and to materials comprising such networks or structures. Typically, the three-dimensional structure comprises an electrical circuit or network comprising one or more of the nanoscale wires, in contrast with structures containing nanoscale wires that may be embedded within a material, but are not electrically active or connected to an electrical circuit. For instance, in some cases, the nanoscale wires may be formed as one or more electrical circuits within the three-dimensional structure, and in some cases, a network of such nanoscale wires may be formed as part of one or more electrical circuits. In addition, as mentioned, at least some of the nanoscale wires may form a portion of an electrical circuit that extends externally of the three-dimensional structure in some cases.

As mentioned, in one set of embodiments, a three-dimensional structure is formed by manipulating a 2-dimensional structure, e.g., by folding or rolling the structure, to from the final three-dimensional structure. It should be understood that although the 2-dimensional structure can be described as having an overall length, width, and height, the overall length and width of the structure may each be substantially greater than the overall height of the structure. Thus, the 2-dimensional structure may be substantially planar. However, the 2-dimensional structure may be manipulated to have a different shape that is 3-dimensional, e.g., having an overall length, width, and height where the overall length and width of the structure are not each substantially greater than the overall height of the structure. For instance, the structure may be manipulated to increase the overall height of the material, relative to its overall length and/or width, for example, by folding or rolling the structure. Thus, for example, a relatively planar sheet of material (having a length and width much greater than its thickness) may be rolled up into a “tube,” such that the tube has an overall length, width, and height of relatively comparable dimensions).

Thus, for example, the 2-dimensional structure may comprise one or more nanoscale wires formed into a 2-dimensional structure or network that is subsequently formed into a 3-dimensional structure. In some embodiments, the 2-dimensional structure may be rolled or curled up to form the 3-dimensional structure, or the 2-dimensional structure may be folded or creased one or more times to form the 3-dimensional structure. Such manipulations can be regular or irregular. In certain embodiments, as discussed herein, the manipulations are caused by pre-stressing the 2-dimensional structure such that it spontaneously forms the 3-dimensional structure, although in other embodiments, such manipulations can be performed separately, e.g., after formation of the 2-dimensional structure.

According to various aspects, a “nanoscale wire” (also known herein as a “nanoscopic-scale wire” or “nanoscopic wire”) generally is a wire or other nanoscale object, that at any point along its length, has at least one cross-sectional dimension and, in some embodiments, two orthogonal cross-sectional dimensions (e.g., a diameter) of less than 1 micrometer, less than about 500 nm, less than about 200 nm, less than about 150 nm, less than about 100 nm, less than about 70, less than about 50 nm, less than about 20 nm, less than about 10 nm, less than about 5 nm, than about 2 nm, or less than about 1 nm. In some embodiments, the nanoscale wire is generally cylindrical. In other embodiments, however, other shapes are possible; for example, the nanoscale wire can be faceted, i.e., the nanoscale wire may have a polygonal cross-section. The cross-section of a nanoscale wire can be of any arbitrary shape, including, but not limited to, circular, square, rectangular, annular, polygonal, or elliptical, and may be a regular or an irregular shape. The nanoscale wire can also be solid or hollow.

In some cases, the nanoscale wire has one dimension that is substantially longer than the other dimensions of the nanoscale wire. For example, the nanoscale wire may have a longest dimension that is at least about 1 micrometer, at least about 3 micrometers, at least about 5 micrometers, or at least about 10 micrometers or about 20 micrometers in length, and/or the nanoscale wire may have an aspect ratio (longest dimension to shortest orthogonal dimension) of greater than about 2:1, greater than about 3:1, greater than about 4:1, greater than about 5:1, greater than about 10:1, greater than about 25:1, greater than about 50:1, greater than about 75:1, greater than about 100:1, greater than about 150:1, greater than about 250:1, greater than about 500:1, greater than about 750:1, or greater than about 1000:1 or more in some cases.

In some embodiments, a nanoscale wire are substantially uniform, or have a variation in average diameter of the nanoscale wire of less than about 30%, less than about 25%, less than about 20%, less than about 15%, less than about 10%, or less than about 5%. For example, the nanoscale wires may be grown from substantially uniform nanoclusters or particles, e.g., colloid particles. See, e.g., U.S. Pat. No. 7,301,199, issued Nov. 27, 2007, entitled “Nanoscale Wires and Related Devices,” by Lieber, et al., incorporated herein by reference in its entirety. In some cases, the nanoscale wire may be one of a population of nanoscale wires having an average variation in diameter, of the population of nanowires, of less than about 30%, less than about 25%, less than about 20%, less than about 15%, less than about 10%, or less than about 5%.

In some embodiments, a nanoscale wire has a conductivity of or of similar magnitude to any semiconductor or any metal. The nanoscale wire can be formed of suitable materials, e.g., semiconductors, metals, etc., as well as any suitable combinations thereof. In some cases, the nanoscale wire will have the ability to pass electrical charge, for example, being electrically conductive. For example, the nanoscale wire may have a relatively low resistivity, e.g., less than about 10⁻³ Ohm m, less than about 10′ Ohm m, less than about 10⁻⁶ Ohm m, or less than about 10⁻⁷ Ohm m. The nanoscale wire can, in some embodiments, have a conductance of at least about 1 microsiemens, at least about 3 microsiemens, at least about 10 microsiemens, at least about 30 microsiemens, or at least about 100 microsiemens.

The nanoscale wire can be solid or hollow, in various embodiments. As used herein, a “nanotube” is a nanoscale wire that is hollow, or that has a hollowed-out core, including those nanotubes known to those of ordinary skill in the art. As another example, a nanotube may be created by creating a core/shell nanowire, then etching away at least a portion of the core to leave behind a hollow shell. Accordingly, in one set of embodiments, the nanoscale wire is a non-carbon nanotube. In contrast, a “nanowire” is a nanoscale wire that is typically solid (i.e., not hollow). Thus, in one set of embodiments, the nanoscale wire may be a semiconductor nanowire, such as a silicon nanowire.

For example, in one embodiment, a nanoscale wire may comprise or consist essentially of a metal. Non-limiting examples of potentially suitable metals include aluminum, gold, silver, copper, molybdenum, tantalum, titanium, nickel, tungsten, chromium, or palladium. In another set of embodiments, a nanoscale wire comprises or consists essentially of a semiconductor. Typically, a semiconductor is an element having semiconductive or semi-metallic properties (i.e., between metallic and non-metallic properties). An example of a semiconductor is silicon. Other non-limiting examples include elemental semiconductors, such as gallium, germanium, diamond (carbon), tin, selenium, tellurium, boron, or phosphorous. In other embodiments, more than one element may be present in the nanoscale wire as the semiconductor, for example, gallium arsenide, gallium nitride, indium phosphide, cadmium selenide, etc. Still other examples include a Group II-VI material (which includes at least one member from Group II of the Periodic Table and at least one member from Group VI, for example, ZnS, ZnSe, ZnSSe, ZnCdS, CdS, or CdSe), or a Group III-V material (which includes at least one member from Group III and at least one member from Group V, for example GaAs, GaP, GaAsP, InAs, InP, AlGaAs, or InAsP).

In certain embodiments, the semiconductor can be undoped or doped (e.g., p-type or n-type). For example, in one set of embodiments, a nanoscale wire may be a p-type semiconductor nanoscale wire or an n-type semiconductor nanoscale wire, and can be used as a component of a transistor such as a field effect transistor (“FET”). For instance, the nanoscale wire may act as the “gate” of a source-gate-drain arrangement of a FET, while metal leads or other conductive pathways (as discussed herein) are used as the source and drain electrodes.

In some embodiments, a dopant or a semiconductor may include mixtures of Group IV elements, for example, a mixture of silicon and carbon, or a mixture of silicon and germanium. In other embodiments, the dopant or the semiconductor may include a mixture of a Group III and a Group V element, for example, BN, BP, BAs, AlN, AlP, AlAs, AlSb, GaN, GaP, GaAs, GaSb, InN, InP, InAs, or InSb. Mixtures of these may also be used, for example, a mixture of BN/BP/BAs, or BN/AlP. In other embodiments, the dopants may include alloys of Group III and Group V elements. For example, the alloys may include a mixture of AlGaN, GaPAs, InPAs, GaInN, AlGaInN, GaInAsP, or the like. In other embodiments, the dopants may also include a mixture of Group II and Group VI semiconductors. For example, the semiconductor may include ZnO, ZnS, ZnSe, ZnTe, CdS, CdSe, CdTe, HgS, HgSe, HgTe, BeS, BeSe, BeTe, MgS, MgSe, or the like. Alloys or mixtures of these dopants are also be possible, for example, (ZnCd)Se, or Zn(SSe), or the like. Additionally, alloys of different groups of semiconductors may also be possible, for example, a combination of a Group II-Group VI and a Group III-Group V semiconductor, for example, (GaAs)ₓ(ZnS)₁₋ₓ. Other examples of dopants may include combinations of Group IV and Group VI elements, such as GeS, GeSe, GeTe, SnS, SnSe, SnTe, PbO, PbS, PbSe, or PbTe. Other semiconductor mixtures may include a combination of a Group I and a Group VII, such as CuF, CuCl, CuBr, Cut AgF, AgCl, AgBr, AgI, or the like. Other dopant compounds may include different mixtures of these elements, such as BeSiN₂, CaCN₂, ZnGeP₂, CdSnAs₂, ZnSnSb₂, CuGeP₃, CuSi₂P₃, Si₃N₄, Ge₃N₄, Al₂O₃, (Al, Ga, In)₂(S, Se, Te)₃, Al₂CO, (Cu, Ag)(Al, Ga, In, Tl, Fe)(S, Se, Te)₂ and the like.

The doping of the semiconductor to produce a p-type or n-type semiconductor may be achieved via bulk-doping in certain embodiments, although in other embodiments, other doping techniques (such as ion implantation) can be used. Many such doping techniques that can be used will be familiar to those of ordinary skill in the art, including both bulk doping and surface doping techniques. A bulk-doped article (e.g. an article, or a section or region of an article) is an article for which a dopant is incorporated substantially throughout the crystalline lattice of the article, as opposed to an article in which a dopant is only incorporated in particular regions of the crystal lattice at the atomic scale, for example, only on the surface or exterior. For example, some articles are typically doped after the base material is grown, and thus the dopant only extends a finite distance from the surface or exterior into the interior of the crystalline lattice. It should be understood that “bulk-doped” does not define or reflect a concentration or amount of doping in a semiconductor, nor does it necessarily indicate that the doping is uniform. “Heavily doped” and “lightly doped” are terms the meanings of which are clearly understood by those of ordinary skill in the art. In some embodiments, one or more regions comprise a single monolayer of atoms (“delta-doping”). In certain cases, the region may be less than a single monolayer thick (for example, if some of the atoms within the monolayer are absent). As a specific example, the regions may be arranged in a layered structure within the nanoscale wire, and one or more of the regions can be delta-doped or partially delta-doped.

Accordingly, in one set of embodiments, the nanoscale wires may include a heterojunction, e.g., of two regions with dissimilar materials or elements, and/or the same materials or elements but at different ratios or concentrations. The regions of the nanoscale wire may be distinct from each other with minimal cross-contamination, or the composition of the nanoscale wire can vary gradually from one region to the next. The regions may be both longitudinally arranged relative to each other, or radially arranged (e.g., as in a core/shell arrangement) on the nanoscale wire. Each region may be of any size or shape within the wire. The junctions may be, for example, a p/n junction, a p/p junction, an n/n junction, a p/i junction (where i refers to an intrinsic semiconductor), an n/i junction, an i/i junction, or the like. The junction can also be a Schottky junction in some embodiments. The junction may also be, for example, a semiconductor/semiconductor junction, a semiconductor/metal junction, a semiconductor/insulator junction, a metal/metal junction, a metal/insulator junction, an insulator/insulator junction, or the like. The junction may also be a junction of two materials, a doped semiconductor to a doped or an undoped semiconductor, or a junction between regions having different dopant concentrations. The junction can also be a defected region to a perfect single crystal, an amorphous region to a crystal, a crystal to another crystal, an amorphous region to another amorphous region, a defected region to another defected region, an amorphous region to a defected region, or the like. More than two regions may be present, and these regions may have unique compositions or may comprise the same compositions. As one example, a wire can have a first region having a first composition, a second region having a second composition, and a third region having a third composition or the same composition as the first composition. Non-limiting examples of nanoscale wires comprising heterojunctions (including core/shell heterojunctions, longitudinal heterojunctions, etc., as well as combinations thereof) are discussed in U.S. Pat. No. 7,301,199, issued Nov. 27, 2007, entitled “Nanoscale Wires and Related Devices,” by Lieber, et al., incorporated herein by reference in its entirety.

In some embodiments, a nanoscale wire is a bent or a kinked nanoscale wire. A kink is typically a relatively sharp transition or turning between a first substantially straight portion of a wire and a second substantially straight portion of a wire. For example, a nanoscale wire may have 1, 2, 3, 4, or 5 or more kinks. In some cases, the nanoscale wire is formed from a single crystal and/or comprises or consists essentially of a single crystallographic orientation, for example, a <110> crystallographic orientation, a <112> crystallographic orientation, or a <11 2̅0> crystallographic orientation. It should be noted that the kinked region need not have the same crystallographic orientation as the rest of the semiconductor nanoscale wire. In some embodiments, a kink in the semiconductor nanoscale wire may be at an angle of about 120° or a multiple thereof. The kinks can be intentionally positioned along the nanoscale wire in some cases. For example, a nanoscale wire may be grown from a catalyst particle by exposing the catalyst particle to various gaseous reactants to cause the formation of one or more kinks within the nanoscale wire. Non-limiting examples of kinked nanoscale wires, and suitable techniques for making such wires, are disclosed in International Patent Application No. PCT/US2010/050199, filed Sep. 24, 2010, entitled “Bent Nanowires and Related Probing of Species,” by Tian, et al., published as WO 2011/038228 on Mar. 31, 2011, incorporated herein by reference in its entirety.

In one set of embodiments, the nanoscale wire is formed from a single crystal, for example, a single crystal nanoscale wire comprising a semiconductor. A single crystal item may be formed via covalent bonding, ionic bonding, or the like, and/or combinations thereof. While such a single crystal item may include defects in the crystal in some cases, the single crystal item is distinguished from an item that includes one or more crystals, not ionically or covalently bonded, but merely in close proximity to one another.

In some embodiments, the nanoscale wires used herein are individual or free-standing nanoscale wires. For example, an “individual” or a “free-standing” nanoscale wire may, at some point in its life, not be attached to another article, for example, with another nanoscale wire, or the free-standing nanoscale wire may be in solution. This is in contrast to nanoscale features etched onto the surface of a substrate, e.g., a silicon wafer, in which the nanoscale features are never removed from the surface of the substrate as a free-standing article. This is also in contrast to conductive portions of articles which differ from surrounding material only by having been altered chemically or physically, in situ, i.e., where a portion of a uniform article is made different from its surroundings by selective doping, etching, etc. An “individual” or a “free-standing” nanoscale wire is one that can be (but need not be) removed from the location where it is made, as an individual article, and transported to a different location and combined with different components to make a functional device such as those described herein and those that would be contemplated by those of ordinary skill in the art upon reading this disclosure.

In various embodiments, more than one nanoscale wire may be present within the three-dimensional networks or structures comprising nanoscale wires, and/or there may be more than one such network or structure present. The nanoscale wires may each independently be the same or different. For example, the network or structure can comprise at least 5 nanoscale wires, at least about 10 nanoscale wires, at least about 30 nanoscale wires, at least about 50 nanoscale wires, at least about 100 nanoscale wires, at least about 300 nanoscale wires, at least about 1000 nanoscale wires, etc., and/or in some cases, the network or structure may contain no more than about 5000 nanoscale wires, no more than about 3000 nanoscale wires, no more than about 1000 nanoscale wires, no more than about 300 nanoscale wires, no more than about 100 nanoscale wires, no more than about 30 nanoscale wires, etc. The nanoscale wires may be distributed uniformly or non-uniformly throughout the network or structure. In some cases, the nanoscale wires may be distributed at an average density of at least about 10 nanoscale wires/mm³, at least about 30 nanoscale wires/mm³, at least about 50 nanoscale wires/mm³, at least about 75 nanoscale wires/mm³, or at least about 100 nanoscale wires/mm³. In certain embodiments, the nanoscale wires are distributed within the network or structure such that the average separation between a nanoscale wire and its nearest neighboring nanoscale wire is less than about 2 mm, less than about 1 mm, less than about 500 micrometers, less than about 300 micrometers, less than about 100 micrometers, less than about 50 micrometers, less than about 30 micrometers, or less than about 10 micrometers.

Within the network or structure, some or all of the nanoscale wires may be individually electronically addressable. For instance, in some cases, at least about 10%, at least about 20%, at least about 30%, at least about 40%, at least about 50%, at least about 60%, at least about 70%, at least about 80%, at least about 90%, or substantially all of the nanoscale wires within the network or structure may be individually electronically addressable. In some embodiments, an electrical property of a nanoscale wire can be individually determinable (e.g., being partially or fully resolvable without also including the electrical properties of other nanoscale wires), and/or such that the electrical property of a nanoscale wire may be individually controlled (e.g., by applying a desired voltage or current to the nanoscale wire, for instance, without simultaneously applying the voltage or current to other nanoscale wires). In other embodiments, however, at least some of the nanoscale wires can be controlled within the same electronic circuit (e.g., by incorporating the nanoscale wires in series and/or in parallel), such that the nanoscale wires can still be electronically controlled and/or determined.

The nanoscale wire, in some embodiments, may be responsive to a property external of the nanoscale wire, e.g., a chemical property, an electrical property, a physical property, a mechanical property, etc. Such determination may be qualitative and/or quantitative. In some cases, more than one such type of nanoscale wire may be present, e.g., within a three-dimensional network or structure. Thus, the network or structure may be used as a sensor in certain aspects. For example, in one set of embodiments, the nanoscale wire may be responsive to voltage. For instance, the nanoscale wire may exhibits a voltage sensitivity of at least about 5 microsiemens/V; by determining the conductivity of a nanoscale wire, the voltage surrounding the nanoscale wire may thus be determined. In other embodiments, the voltage sensitivity can be at least about 10 microsiemens/V, at least about 30 microsiemens/V, at least about 50 microsiemens/V, or at least about 100 microsiemens/V. Other examples of electrical properties that can be determined include resistance, resistivity, conductance, conductivity, impendence, or the like.

As another example, a nanoscale wire may be responsive to a chemical property of the environment surrounding the nanoscale wire. For example, an electrical property of the nanoscale wire can be affected by a chemical environment surrounding the nanoscale wire, and the electrical property can be thereby determined to determine the chemical environment surrounding the nanoscale wire. As a specific non-limiting example, the nanoscale wires may be sensitive to pH or hydrogen ions. Further non-limiting examples of such nanoscale wires are discussed in U.S. Pat. No. 7,129,554, filed Oct. 31, 2006, entitled “Nanosensors,” by Lieber, et al., incorporated herein by reference in its entirety.

As an example, the nano scale wire may have the ability to bind to an analyte indicative of a chemical property of the environment surrounding the nanoscale wire (e.g., hydrogen ions for pH, or concentration for an analyte of interest), and/or the nanoscale wire may be partially or fully functionalized, i.e. comprising surface functional moieties, to which an analyte is able to bind, thereby causing a determinable property change to the nanoscale wire, e.g., a change to the resistivity or impedance of the nanoscale wire. The binding of the analyte can be specific or non-specific. Functional moieties may include simple groups, selected from the groups including, but not limited to, —OH, —CHO, —COOH, —SO₃H, —CN, —NH₂, —SH, —COSH, —COOR, halide; biomolecular entities including, but not limited to, amino acids, proteins, sugars, DNA, antibodies, antigens, and enzymes; grafted polymer chains with chain length less than the diameter of the nanowire core, selected from a group of polymers including, but not limited to, polyamide, polyester, polyimide, polyacrylic; a shell of material comprising, for example, metals, semiconductors, and insulators, which may be a metallic element, an oxide, an sulfide, a nitride, a selenide, a polymer and a polymer gel.

In some embodiments, a reaction entity may be bound to a surface of the nanoscale wire, and/or positioned in relation to the nanoscale wire such that the analyte can be determined by determining a change in a property of the nanoscale wire. The “determination” may be quantitative and/or qualitative, depending on the application. The term “reaction entity” refers to any entity that can interact with an analyte in such a manner to cause a detectable change in a property (such as an electrical property) of a nanoscale wire. The reaction entity may enhance the interaction between the nanowire and the analyte, or generate a new chemical species that has a higher affinity to the nanowire, or to enrich the analyte around the nanowire. The reaction entity can comprise a binding partner to which the analyte binds. The reaction entity, when a binding partner, can comprise a specific binding partner of the analyte. For example, the reaction entity may be a nucleic acid, an antibody, a sugar, a carbohydrate or a protein. Alternatively, the reaction entity may be a polymer, catalyst, or a quantum dot. A reaction entity that is a catalyst can catalyze a reaction involving the analyte, resulting in a product that causes a detectable change in the nanowire, e.g. via binding to an auxiliary binding partner of the product electrically coupled to the nanowire. Another exemplary reaction entity is a reactant that reacts with the analyte, producing a product that can cause a detectable change in the nanowire. The reaction entity can comprise a shell on the nanowire, e.g. a shell of a polymer that recognizes molecules in, e.g., a gaseous sample, causing a change in conductivity of the polymer which, in turn, causes a detectable change in the nanowire.

The term “binding partner” refers to a molecule that can undergo binding with a particular analyte, or “binding partner” thereof, and includes specific, semi-specific, and non-specific binding partners as known to those of ordinary skill in the art. The term “specifically binds,” when referring to a binding partner (e.g., protein, nucleic acid, antibody, etc.), refers to a reaction that is determinative of the presence and/or identity of one or other member of the binding pair in a mixture of heterogeneous molecules (e.g., proteins and other biologics). Thus, for example, in the case of a receptor/ligand binding pair the ligand would specifically and/or preferentially select its receptor from a complex mixture of molecules, or vice versa. An enzyme would specifically bind to its substrate, a nucleic acid would specifically bind to its complement, an antibody would specifically bind to its antigen. Other examples include, nucleic acids that specifically bind (hybridize) to their complement, antibodies specifically bind to their antigen, and the like. The binding may be by one or more of a variety of mechanisms including, but not limited to ionic interactions, and/or covalent interactions, and/or hydrophobic interactions, and/or van der Waals interactions, etc. For example, the nanoscale wire may exhibit piezoelectric characteristics such that an application of a 10% tensile strain along a nanoscale wire may cause the nanoscale wire to yield an increase of at least about 10 nS, at least about 20 nS, at least about 30 nS, at least about 50 nS, at least about 75 nS, at least about 100 nS, at least about 150 nS, at least about 200 nS, etc.

As yet another example, a nanoscale wire may be responsive to a mechanical property of the environment surrounding the nanoscale wire. For example, certain types of silicon nanoscale wires may have a high piezoresistance response, such that changes in mechanical strain surrounding a nanoscale wire may be exhibited as changes in resistance within the nanoscale wire, which may be determined to determine the mechanical strain experienced by the nanoscale wire.

In some embodiments, the three-dimensional network or structure may be one that contains sufficient nanoscale wires that a property, such as a chemical, mechanical, or an electrical property, can be determined at a relatively high resolution, and/or in three dimensions within the three-dimensional network or structure, e.g., due to the placement of nanoscale wires within the network or structure that can be used as sensors. For example, one or more nanoscale wires may be present within an electronic circuit as a component of a field effect transistor. In addition, in certain embodiments, such determinations may be transmitted and/or recorded, e.g., for later use and or analysis.

Thus, for example, a property such as a chemical property, a mechanical property, an electrical property, etc. can be determined at a resolution of less than about 2 mm, less than about 1 mm, less than about 500 micrometers, less than about 300 micrometers, less than about 100 micrometers, less than about 50 micrometers, less than about 30 micrometers, or less than about 10 micrometers, etc., e.g., due to the average separation between a nanoscale wire and its nearest neighboring nanoscale wire. In addition, as mentioned, the property may be determined within the network or structure in three dimensions in some instances, in contrast with many other techniques where only a surface of a material can be studied. Accordingly, very high resolution and/or 3-dimensional mappings of the property of the network or structure can be obtained in some embodiments.

In addition, in some cases, such properties can be determined and/or recorded as a function of time. Thus, for example, such properties can be determined at a time resolution of less than about 1 min, less than about 30 s, less than about 15 s, less than about 10 s, less than about 5 s, less than about 3 s, less than about 1 s, less than about 500 ms, less than about 300 ms, less than about 100 ms, less than about 50 ms, less than about 30 ms, less than about 10 ms, less than about 5 ms, less than about 3 ms, less than about 1 ms, etc.

In yet another set of embodiments, the three-dimensional network or structure, and/or portions of the three-dimensional network or structure, may be electrically stimulated using nanoscale wires present within the network or structure. For example, all, or a subset of the electrically active nanoscale wires may be electrically stimulated, e.g., by using an external electrical system, such as a computer. Thus, for example, a single nanoscale wire, a group of nanoscale wires, or substantially all of the nanoscale wires can be electrically stimulated, depending on the particular application. In some cases, such nanoscale wires can be stimulated in a particular pattern.

Some or all of the nanoscale wires may be in electrical communication with a surface of the three-dimensional network or structure via one or more conductive pathways, in certain aspects of the invention. In some embodiments, conductive pathways can be used to determine a property of a nanoscale wire (for example, an electrical property or a chemical property as is discussed herein), and/or the conductive pathway may be used to direct an electrical signal to the nanoscale wire, e.g., to electrically stimulate cells proximate the nanoscale wire. The conductive pathways can form an electrical circuit that is internally contained within the three-dimensional network or structure, and/or that extends externally of the three-dimensional network or structure, e.g., such that the electrical circuit is in electrical communication with an external electrical system, such as a computer or a transmitter (for instance, a radio transmitter, a wireless transmitter, an Internet connection, etc.). Any suitable pathway conductive pathway may be used, for example, pathways comprising metals, semiconductors, conductive polymers, or the like.

In some embodiments, more than one conductive pathway may be used within a three-dimensional network or structure. For example, multiple conductive pathways can be used such that some or all of the nanoscale wires may be individually electronically addressable within the three-dimensional network or structure. However, in other embodiments, more than one nanoscale wire may be addressable by a particular conductive pathway. In addition, in some cases, other electronic components may also be present within the three-dimensional network or structure, e.g., as part of a conductive pathway or otherwise forming part of an electrical circuit. Examples include, but are not limited to, transistors such as field effect transistors, resistors, capacitors, inductors, diodes, integrated circuits, etc. In some cases, some of these may also comprise nanoscale wires.

In some embodiments, the conductive pathway may be relatively narrow. For example, the conductive pathway may have a smallest dimension or a largest cross-sectional dimension of less than about 5 micrometers, less than about 4 micrometers, less than about 3 micrometers, less than about 2 micrometers, less than about 1 micrometer, less than about 700 nm, less than about 600 nm, less than about 500 nm, less than about 300 nm, less than about 200 nm, less than about 100 nm, less than about 80 nm, less than about 50 nm, less than about 30 nm, less than about 10 nm, less than about 5 nm, less than about 2 nm, etc. The conductive pathway may have any suitable cross-sectional shape, e.g., circular, square, rectangular, polygonal, elliptical, regular, irregular, etc. As is discussed in detail below, such conductive pathways may be achieved using lithographic or other techniques.

A given conductive pathway within a three-dimensional network or structure may be in electrical communication with any number of nanoscale wires within a three-dimensional network or structure, depending on the embodiment. For example, a conductive pathway can be in electrical communication with one, two, three, or more nanoscale wires, and if more than one nanoscale wire is used within a given conductive pathway, the nanoscale wires may each independently be the same or different. Thus, for example, an electrical property of the nanoscale wire may be determined via the conductive pathway, and/or a signal can be propagated via the conductive pathway to the nanoscale wire. In addition, as previously discussed, some or all of the nanoscale wires may be in electrical communication with a surface of the network or structure via one or more conductive pathways. For example, in some cases, at least about 10%, at least about 20%, at least about 30%, at least about 40%, at least about 50%, at least about 60%, at least about 70%, at least about 80%, or at least about 90% of the nanoscale wires within the network or structure may be in electrical communication with one or more conductive pathways, or otherwise form portions of one or more electrical circuits extending externally of the network or structure. In some cases, however, not all of the nanoscale wires within a three-dimensional network or structure may be in electrical communication with one or more conductive pathways, e.g., by design, or because of inefficiencies within the fabrication process, etc.

In some embodiments, one or more metal leads can be used within a conductive pathway to a nanoscale wire. The metal lead may directly physically contact the nanoscale wire and/or there may be other materials between the metal lead and the nanoscale wire that allow electrical communication to occur. Metal leads are useful due to their high conductance, e.g., such that changes within electrical properties obtained from the conductive pathway can be related to changes in properties of the nanoscale wire, rather than changes in properties of the conductive pathway. However, it is not a requirement that only metal leads be used, and in other embodiments, other types of conductive pathways may also be used, in addition or instead of metal leads.

A wide variety of metal leads can be used, in various embodiments of the invention. As non-limiting examples, the metals used within a metal lead may include aluminum, gold, silver, copper, molybdenum, tantalum, titanium, nickel, tungsten, chromium, palladium, as well as any combinations of these and/or other metals. In some cases, the metal can be chosen to be one that is readily introduced into the three-dimensional network or structure, e.g., using techniques compatible with lithographic techniques. For example, in one set of embodiments, lithographic techniques such as e-beam lithography, photolithography, X-ray lithography, extreme ultraviolet lithography, ion projection lithography, etc. may be used to layer or deposit one or more metals on a substrate. Additional processing steps can also be used to define or register the metal leads in some cases. Thus, for example, the thickness of a metal layer may be less than about 5 micrometers, less than about 4 micrometers, less than about 3 micrometers, less than about 2 micrometers, less than about 1 micrometer, less than about 700 nm, less than about 600 nm, less than about 500 nm, less than about 300 nm, less than about 200 nm, less than about 100 nm, less than about 80 nm, less than about 50 nm, less than about 30 nm, less than about 10 nm, less than about 5 nm, less than about 2 nm, etc. The thickness of the layer may also be at least about 10 nm, at least about 20 nm, at least about 40 nm, at least about 60 nm, at least about 80 nm, or at least about 100 nm. For example, the thickness of a layer may be between about 40 nm and about 100 nm, between about 50 nm and about 80 nm.

In some embodiments, more than one metal can be used within a metal lead. For example, two, three, or more metals may be used within a metal lead. The metals may be deposited in different regions or alloyed together, or in some cases, the metals may be layered on top of each other, e.g., layered on top of each other using various lithographic techniques. For example, a second metal may be deposited on a first metal, and in some cases, a third metal may be deposited on the second metal, etc. Additional layers of metal (e.g., fourth, fifth, sixth, etc.) may also be used in some embodiments. The metals can all be different, or in some cases, some of the metals (e.g., the first and third metals) may be the same. Each layer may independently be of any suitable thickness or dimension, e.g., of the dimensions described above, and the thicknesses of the various layers can independently be the same or different.

If dissimilar metals are layered on top of each other, they may be layered in some embodiments in a “stressed” configuration (although in other embodiments they may not necessarily be stressed). As a specific non-limiting example, chromium and palladium can be layered together to cause stresses in the metal leads to occur, thereby causing warping or bending of the metal leads. The amount and type of stress may also be controlled, e.g., by controlling the thicknesses of the layers. For example, relatively thinner layers can be used to increase the amount of warping that occurs.

Without wishing to be bound by any theory, it is believed that layering metals having a difference in stress (e.g., film stress) with respect to each other may, in some cases, cause stresses within the metal, which can cause bending or warping as the metals seek to relieve the stresses. In some embodiments, such mismatches are undesirable because they could cause warping of the metal leads and thus, the three-dimensional network or structure. However, in other embodiments, such mismatches may be desired, e.g., so that the network or structure can be intentionally deformed to form a 3-dimensional structure, as discussed herein. In addition, in certain embodiments, the deposition of mismatched metals within a lead may occur at specific locations within the network or structure, e.g., to cause specific warpings to occur, which can be used to cause the network or structure to be deformed into a particular shape or configuration. For example, a “line” of such mismatches can be used to cause an intentional bending or folding along the line of the network or structure, or the network or structure may be caused to roll, e.g., into a cylinder or a “scroll.”

In one aspect, the three-dimensional network or structure may also contain one or more polymers or polymeric constructs. The polymeric constructs typically comprise one or more polymers, e.g., photoresists, biocompatible polymers, biodegradable polymers, etc., and optionally may contain other materials, for example, metal leads or other conductive pathway materials. The polymeric constructs may be separately formed then assembled into the three-dimensional network or structure, and/or the polymeric constructs may be integrally formed as part of the network or structure, for example, by forming or manipulating (e.g. folding, rolling, etc.) the polymeric constructs into a 3-dimensional structure that defines the three-dimensional network or structure.

In one set of embodiments, some or all of the polymeric constructs have the form of fibers or ribbons. For example, the polymeric constructs may have one dimension that is substantially longer than the other dimensions of the polymeric construct. The fibers can in some cases be joined together to form a network or “mesh” of fibers that define a three-dimensional network or structure. For example, referring to FIG. 2A, III, a three-dimensional network or structure may contain a plurality of fibers that are orthogonally arranged to form a regular network or structure of polymeric constructs. However, the polymeric constructs need not be regularly arranged. In addition, it should be noted that although FIG. 2A shows only polymer constructs having the form of fibers, this is by way of example only, and in other embodiments, other shapes of polymeric constructs can be used. In general, any shape or dimension of polymeric construct may be used.

Thus, for example, in one set of embodiments, some or all of the polymeric constructs have a smallest dimension or a largest cross-sectional dimension of less than about 5 micrometers, less than about 4 micrometers, less than about 3 micrometers, less than about 2 micrometers, less than about 1 micrometer, less than about 700 nm, less than about 600 nm, less than about 500 nm, less than about 300 nm, less than about 200 nm, less than about 100 nm, less than about 80 nm, less than about 50 nm, less than about 30 nm, less than about 10 nm, less than about 5 nm, less than about 2 nm, etc. A polymeric construct may also have any suitable cross-sectional shape, e.g., circular, square, rectangular, polygonal, elliptical, regular, irregular, etc. Examples of methods of forming polymeric constructs, e.g., by lithographic or other techniques, are discussed below.

In one set of embodiments, the polymeric constructs may be constructed and arranged within the three-dimensional network or structure such that the network or structure has an free volume or an open porosity of at least about 30%, at least about 40%, at least about 50%, at least about 60%, at least about 70%, at least about 75%, at least about 80%, at least about 85%, at least about 90%, at least about 95%, at least about 97, at least about 99%, at least about 99.5%, or at least about 99.8%. The “free volume” is generally described as the volume of empty space within the three-dimensional network or structure divided by the overall volume defined by the network or structure, and can be thought of as being equivalent to void volume.

In some cases, a “two-dimensional open porosity” may also be defined, e.g., of an initial network that is subsequently formed or manipulated into a three-dimensional network or structure. The two-dimensional open porosities of a network or structure can be defined as the void area within the two-dimensional configuration of the network or structure (e.g., where no material is present) divided by the overall area of network or structure, and can be determined before or after the network or structure has been formed into a 3-dimensional structure. Depending on the application, a network or structure may have a two-dimensional open porosity of at least about 30%, at least about 40%, at least about 50%, at least about 60%, at least about 70%, at least about 75%, at least about 80%, at least about 85%, at least about 90%, at least about 95%, at least about 97, at least about 99%, at least about 99.5%, or at least about 99.8%, etc.

Another method of generally determining the two-dimensional porosity of the network or structure is by determining the areal mass density, i.e., the mass of the network or structure divided by the area of one face of the network or structure (including holes or voids present therein). Thus, for example, in another set of embodiments, the three-dimensional network or structure may have an areal mass density of less than about 100 micrograms/cm², less than about 80 micrograms/cm², less than about 60 micrograms/cm², less than about 50 micrograms/cm², less than about 40 micrograms/cm², less than about 30 micrograms/cm², or less than about 20 micrograms/cm².

The porosity of a three-dimensional network or structure can be defined by one or more pores. In one set of embodiments, the three-dimensional network or structure may have an average pore size of at least about 100 micrometers, at least about 200 micrometers, at least about 300 micrometers, at least about 400 micrometers, at least about 500 micrometers, at least about 600 micrometers, at least about 700 micrometers, at least about 800 micrometers, at least about 900 micrometers, or at least about 1 mm. In some cases, the network or structure may have an average pore size of no more than about 1.5 mm, no more than about 1.4 mm, no more than about 1.3 mm, no more than about 1.2 mm, no more than about 1.1 mm, no more than about 1 mm, no more than about 900 micrometers, no more than about 800 micrometers, no more than about 700 micrometers, no more than about 600 micrometers, or no more than about 500 micrometers. Combinations of these are also possible, e.g., in one embodiment, the average pore size is at least about 100 micrometers and no more than about 1.5 mm. In addition, larger or smaller pores than these can also be used in a network or structure in certain cases. Pore sizes may be determined using any suitable technique, e.g., through visual inspection, BET measurements, or the like.

In various embodiments, one or more of the polymers forming a polymeric construct may be a photoresist. Photoresists are typically used in lithographic techniques, which can be used as discussed herein to form the polymeric construct. For example, the photoresist may be chosen for its ability to react to light to become substantially insoluble (or substantially soluble, in some cases) to a photoresist developer. For instance, photoresists that can be used within a polymeric construct include, but are not limited to, SU-8, S1805, LOR 3A, poly(methyl methacrylate), poly(methyl glutarimide), phenol formaldehyde resin (diazonaphthoquinone/novolac), diazonaphthoquinone (DNQ), Hoechst AZ 4620, Hoechst AZ 4562, Shipley 1400-17, Shipley 1400-27, Shipley 1400-37, or the like. These and many other photoresists are available commercially.

The polymers and other components forming the three-dimensional network or structure can also be used in some embodiments to provide a certain degree of flexibility to the three-dimensional network or structure, which can be quantified, for example, as a bending stiffness per unit width. An example method for determining the bending stiffness is discussed below. In various embodiments, the network or structure may have a bending stiffness of less than about 5 nN m, less than about 4.5 nN m, less than about 4 nN m, less than about 3.5 nN m, less than about 3 nN m, less than about 2.5 nN m, less than about 2 nN m, less than about 1.5 nN m, or less than about 1 nN m.

In some aspects, the three-dimensional network or structure can include a 2-dimensional structure that is formed into a final network or structure, e.g., by folding or rolling the structure. It should be understood that although the 2-dimensional structure can be described as having an overall length, width, and height, the overall length and width of the structure may each be substantially greater than the overall height of the structure. The 2-dimensional structure may also be manipulated to have a different shape that is 3-dimensional, e.g., having an overall length, width, and height where the overall length and width of the structure are not each substantially greater than the overall height of the structure. For instance, the structure may be manipulated to increase the overall height of the material, relative to its overall length and/or width, for example, by folding or rolling the structure. Thus, for example, a relatively planar sheet of material (having a length and width much greater than its thickness) may be rolled up into a “tube,” such that the tube has an overall length, width, and height of relatively comparable dimensions).

Thus, for example, the 2-dimensional structure may comprise one or more nanoscale wires and one or more polymeric constructs formed into a 2-dimensional structure or network that is subsequently formed into a 3-dimensional structure. In some embodiments, the 2-dimensional structure may be rolled or curled up to form the 3-dimensional structure, or the 2-dimensional structure may be folded or creased one or more times to form the 3-dimensional structure. Such manipulations can be regular or irregular. In certain embodiments, as discussed herein, the manipulations are caused by pre-stressing the 2-dimensional structure such that it spontaneously forms the 3-dimensional structure, although in other embodiments, such manipulations can be performed separately, e.g., after formation of the 2-dimensional structure.

The three-dimensional structure may be present within another material, in certain embodiments of the invention. For example, in some cases, the three-dimensional structure may be partially or completely embedded within another material. In some cases, for instance, a portion of the three-dimensional structure may not be embedded so as to permit access of nanoscale wires within the three-dimensional structure. For example, there may be portions of the three-dimensional structure that are not embedded that can be connected to an external electrical circuit, e.g., to electronically interrogate or otherwise determine the electronic state or one or more of the nanoscale wires within the three-dimensional structure, and or to electronically stimulate one or more of the nanoscale wires within the three-dimensional structure.

For example, in one set of embodiments, the material may be a metal. For example, the metal may be added to the three-dimensional structure as shavings or small particles and annealed or heated to form a larger metal material, e.g., containing or embedding the three-dimensional structure. For example, the metal may include low-melting metals such as mercury-containing alloys, gallium-containing alloys, or solders comprising bismuth, lead, tin, cadmium, zinc, indium, thallium, or the like.

As another example, the material may be a polymer, e.g., comprising naturally occurring monomers and/or non-naturally occurring monomers. Any of wide variety of polymers may be used, including polydimethylsiloxane, rubber, isoprenes, or the like. For instance, in one set of embodiments, the polymer is a gel. Non-limiting examples of gels include agarose, polyacrylamide, methylcellulose, hyaluronan, or other naturally derived polymers. For example, acrylamide monomer or fluid agarose may be added to a three-dimensional structure and solidified to form a gel, e.g., at least partially embedding the three-dimensional structure. In another set of embodiments, the polymer may include a fabric or a fiber. For instance, the fabric may comprise fibers such as wool, silk, cotton, aramid, acrylic, nylon, spandex, rayon, polyester, or the like. For instance, one or more fibers (and/or other materials described herein) may be inserted into a three-dimensional structure, and used to form articles of clothing, footwear (e.g., shoes, sneakers, boots, etc.), or the like.

As a non-limiting example, in certain embodiments, the material may be used to define one or more channels, e.g., microfluidic channels, or other channels for the flow of a fluid. For example, least a portion of a wall of the channel may comprise a three-dimensional structure, which can be used to monitor a condition or property of fluid within the channel.

In various aspects, three-dimensional network or structures comprising nanoscale wires such as those described herein may be used in a wide variety of applications. In some cases, at least some of the nanoscale wires form a portion of an electrical circuit that extends externally of the three-dimensional network or structure, e.g., for connection to external devices. For example, in some cases, some or all of the conductive pathways can also be connected to an external electrical system, such as a computer, a transmitter, a receiver, etc., e.g., a radio transmitter, a wireless transmitter, etc. In some cases, the three-dimensional network may itself comprise a transmitter and/or a receiver. For example, the three-dimensional network may incorporate suitable circuit elements that it can be used as an RFID tag or can be used in conjunction with local positioning systems.

Another aspect of the present invention is generally directed to systems and methods for making and using such three-dimensional networks or structures. Briefly, in one set of embodiments, a three-dimensional structure is constructed by assembling various polymers, metals, nanoscale wires, and other components together on a substrate. For example, lithographic techniques such as e-beam lithography, photolithography, X-ray lithography, extreme ultraviolet lithography, ion projection lithography, etc. may be used to pattern polymers, metals, etc. on the substrate, and nanoscale wires can be prepared separately then added to the substrate. After assembly, at least a portion of the substrate (e.g., a sacrificial material) may be removed, allowing the three-dimensional structure to be partially or completely removed from the substrate. The three-dimensional structure can, in some cases, be formed into a 3-dimensional structure, for example, spontaneously, or by folding or rolling the structure. Other materials may also be added to the three-dimensional structure, e.g., to help stabilize the structure, to add additional agents to enhance its biocompatibility, etc.

The substrate may be chosen to be one that can be used for lithographic techniques such as e-beam lithography or photolithography, or other lithographic techniques including those discussed herein. For example, the substrate may comprise or consist essentially of a semiconductor material such as silicon, although other substrate materials (e.g., a metal) can also be used. Typically, the substrate is one that is substantially planar, e.g., so that polymers, metals, and the like can be patterned on the substrate.

In some cases, a portion of the substrate can be oxidized, e.g., forming SiO₂ and/or Si₃N₄ on a portion of the substrate, which may facilitate subsequent addition of materials (metals, polymers, etc.) to the substrate. In some cases, the oxidized portion may form a layer of material on the substrate, e.g., having a thickness of less than about 5 micrometers, less than about 4 micrometers, less than about 3 micrometers, less than about 2 micrometers, less than about 1 micrometer, less than about 900 nm, less than about 800 nm, less than about 700 nm, less than about 600 nm, less than about 500 nm, less than about 400 nm, less than about 300 nm, less than about 200 nm, less than about 100 nm, etc.

Optionally, one or more polymers can also be deposited or otherwise formed prior to depositing the sacrificial material. In some cases, the polymers may be deposited or otherwise formed as a layer of material on the substrate. Deposition may be performed using any suitable technique, e.g., using lithographic techniques such as e-beam lithography, photolithography, X-ray lithography, extreme ultraviolet lithography, ion projection lithography, etc. The polymers that are deposited may comprise methyl methacrylate and/or poly(methyl methacrylate), in some embodiments. One, two, or more layers of polymer can be deposited (e.g., sequentially) in various embodiments, and each layer may independently have a thickness of less than about 5 micrometers, less than about 4 micrometers, less than about 3 micrometers, less than about 2 micrometers, less than about 1 micrometer, less than about 900 nm, less than about 800 nm, less than about 700 nm, less than about 600 nm, less than about 500 nm, less than about 400 nm, less than about 300 nm, less than about 200 nm, less than about 100 nm, etc.

Next, a sacrificial material may be deposited. The sacrificial material can be chosen to be one that can be removed without substantially altering other materials (e.g., polymers, other metals, nanoscale wires, etc.) deposited thereon. For example, in one embodiment, the sacrificial material may be a metal, e.g., one that is easily etchable. For instance, the sacrificial material can comprise germanium or nickel, which can be etched or otherwise removed, for example, using a peroxide (e.g., H₂O₂) or a nickel etchant (many of which are readily available commercially). In some cases, the sacrificial material may be deposited on oxidized portions or polymers previously deposited on the substrate. In some cases, the sacrificial material is deposited as a layer. The layer can have a thickness of less than about 5 micrometers, less than about 4 micrometers, less than about 3 micrometers, less than about 2 micrometers, less than about 1 micrometer, less than about 900 nm, less than about 800 nm, less than about 700 nm, less than about 600 nm, less than about 500 nm, less than about 400 nm, less than about 300 nm, less than about 200 nm, less than about 100 nm, etc.

In some embodiments, a “bedding” polymer can be deposited, e.g., on the sacrificial material. The bedding polymer may include one or more polymers, which may be deposited as one or more layers. The bedding polymer can be used to support the nanoscale wires, and in some cases, partially or completely surround the nanoscale wires, depending on the application. For example, as discussed below, one or more nanoscale wires may be deposited on at least a portion of the uppermost layer of bedding polymer.

In one set of embodiments, the bedding polymer may be deposited as a layer of material, such that portions of the bedding polymer may be subsequently removed. For example, the bedding polymer can be deposited using lithographic techniques such as e-beam lithography, photolithography, X-ray lithography, extreme ultraviolet lithography, ion projection lithography, etc., or using other techniques for removing polymer that are known to those of ordinary skill in the art. In some cases, more than one bedding polymer is used, e.g., deposited as more than one layer (e.g., sequentially), and each layer may independently have a thickness of less than about 5 micrometers, less than about 4 micrometers, less than about 3 micrometers, less than about 2 micrometers, less than about 1 micrometer, less than about 900 nm, less than about 800 nm, less than about 700 nm, less than about 600 nm, less than about 500 nm, less than about 400 nm, less than about 300 nm, less than about 200 nm, less than about 100 nm, etc. For example, in some embodiments, portions of the photoresist may be exposed to light (visible, UV, etc.), electrons, ions, X-rays, etc. (e.g., projected onto the photoresist), and the exposed portions can be etched away (e.g., using suitable etchants, plasma, etc.) to produce the pattern.

Accordingly, the bedding polymer may be formed into a particular pattern, e.g., in a grid, before or after deposition of nanoscale wires (as discussed in detail below), in certain embodiments of the invention. The pattern can be regular or irregular. For example, the bedding polymer can be formed into a pattern defining pore sizes such as those discussed herein. For instance, the polymer may have an average pore size of at least about 100 micrometers, at least about 200 micrometers, at least about 300 micrometers, at least about 400 micrometers, at least about 500 micrometers, at least about 600 micrometers, at least about 700 micrometers, at least about 800 micrometers, at least about 900 micrometers, or at least about 1 mm, and/or an average pore size of no more than about 1.5 mm, no more than about 1.4 mm, no more than about 1.3 mm, no more than about 1.2 mm, no more than about 1.1 mm, no more than about 1 mm, no more than about 900 micrometers, no more than about 800 micrometers, no more than about 700 micrometers, no more than about 600 micrometers, or no more than about 500 micrometers, etc.

Any suitable polymer may be used as the bedding polymer. In certain embodiments, one or more of the bedding polymers may comprise a photoresist. Photoresists can be useful due to their familiarity in use in lithographic techniques such as those discussed herein. Non-limiting examples of photoresists include SU-8, S1805, LOR 3A, poly(methyl methacrylate), poly(methyl glutarimide), phenol formaldehyde resin (diazonaphthoquinone/novolac), diazonaphthoquinone (DNQ), Hoechst AZ 4620, Hoechst AZ 4562, Shipley 1400-17, Shipley 1400-27, Shipley 1400-37, etc., as well as any others discussed herein.

In certain embodiments, one or more of the bedding polymers can be heated or baked, e.g., before or after depositing nanoscale wires thereon as discussed below, and/or before or after patterning the bedding polymer. For example, such heating or baking, in some cases, is important to prepare the polymer for lithographic patterning. In various embodiments, the bedding polymer may be heated to a temperature of at least about 30° C., at least about 65° C., at least about 95° C., at least about 150° C., or at least about 180° C., etc.

Next, one or more nanoscale wires may be deposited, e.g., on a bedding polymer on the substrate. Any of the nanoscale wires described herein may be used, e.g., n-type and/or p-type nanoscale wires, substantially uniform nanoscale wires (e.g., having a variation in average diameter of less than 20%), nanoscale wires having a diameter of less than about 1 micrometer, semiconductor nanowires, silicon nanowires, bent nanoscale wires, kinked nanoscale wires, core/shell nanowires, nanoscale wires with heterojunctions, etc. In some cases, the nanoscale wires are present in a liquid which is applied to the substrate, e.g., poured, painted, or otherwise deposited thereon. In some embodiments, the liquid is chosen to be relatively volatile, such that some or all of the liquid can be removed by allowing it to substantially evaporate, thereby depositing the nanoscale wires. In some cases, at least a portion of the liquid can be dried off, e.g., by applying heat to the liquid. Examples of suitable liquids include water or isopropanol.

In some cases, at least some of the nanoscale wires may be at least partially aligned, e.g., as part of the deposition process, and/or after the nanoscale wires have been deposited on the substrate. Thus, the alignment can occur before or after drying or other removal of the liquid, if a liquid is used. Any suitable technique may be used for alignment of the nanoscale wires. For example, the nanoscale wires can be aligned by passing or sliding substrates containing the nanoscale wires past each other (see, e.g., International Patent Application No. PCT/US2007/008540, filed Apr. 6, 2007, entitled “Nanoscale Wire Methods and Devices,” by Nam, et al., published as WO 2007/145701 on Dec. 21, 2007, incorporated herein by reference in its entirety), the nanoscale wires can be aligned using Langmuir-Blodgett techniques (see, e.g., U.S. patent application Ser. No. 10/995,075, filed Nov. 22, 2004, entitled “Nanoscale Arrays and Related Devices,” by Whang, et al., published as U.S. Patent Application Publication No. 2005/0253137 on Nov. 17, 2005, incorporated herein by reference in its entirety), the nanoscale wires can be aligned by incorporating the nanoscale wires in a liquid film or “bubble” which is deposited on the substrate (see, e.g., U.S. patent application Ser. No. 12/311,667, filed Apr. 8, 2009, entitled “Liquid Films Containing Nanostructured Materials,” by Lieber, et al., published as U.S. Patent Application Publication No. 2010/0143582 on Jun. 10, 2010, incorporated by reference herein in its entirety), or a gas or liquid can be passed across the nanoscale wires to align the nanoscale wires (see, e.g., U.S. Pat. No. 7,211,464, issued May 1, 2007, entitled “Doped Elongated Semiconductors, Growing Such Semiconductors, Devices Including Such Semiconductors, and Fabricating Such Devices,” by Lieber, et al.; and U.S. Pat. No. 7,301,199, issued Nov. 27, 2007, entitled “Nanoscale Wires and Related Devices,” by Lieber, et al., each incorporated herein by reference in its entirety). Combinations of these and/or other techniques can also be used in certain instances. In some cases, the gas may comprise an inert gas and/or a noble gas, such as nitrogen or argon.

In certain embodiments, a “lead” polymer is deposited, e.g., on the sacrificial material and/or on at least some of the nanoscale wires. The lead polymer may include one or more polymers, which may be deposited as one or more layers. The lead polymer can be used to cover or protect metal leads or other conductive pathways, which may be subsequently deposited on the lead polymer. In some embodiments, the lead polymer can be deposited, e.g., as a layer of material such that portions of the lead polymer can be subsequently removed, for instance, using lithographic techniques such as e-beam lithography, photolithography, X-ray lithography, extreme ultraviolet lithography, ion projection lithography, etc., or using other techniques for removing polymer that are known to those of ordinary skill in the art, similar to the bedding polymers previously discussed. However, the lead polymers need not be the same as the bedding polymers (although they can be), and they need not be deposited using the same techniques (although they can be). In some cases, more than one lead polymer may be used, e.g., deposited as more than one layer (for example, sequentially), and each layer may independently have a thickness of less than about 5 micrometers, less than about 4 micrometers, less than about 3 micrometers, less than about 2 micrometers, less than about 1 micrometer, less than about 900 nm, less than about 800 nm, less than about 700 nm, less than about 600 nm, less than about 500 nm, less than about 400 nm, less than about 300 nm, less than about 200 nm, less than about 100 nm, etc. Any suitable polymer can be used as the lead polymer. For example, in one set of embodiments, one or more of the polymers may comprise poly(methyl methacrylate). In certain embodiments, one or more of the lead polymers comprises a photoresist, such as those described herein.

In certain embodiments, one or more of the lead polymers may be heated or baked, e.g., before or after depositing nanoscale wires thereon as discussed below, and/or before or after patterning the lead polymer. For example, such heating or baking, in some cases, is important to prepare the polymer for lithographic patterning. In various embodiments, the lead polymer may be heated to a temperature of at least about 30° C., at least about 65° C., at least about 95° C., at least about 150° C., or at least about 180° C., etc.

Next, a metal or other conductive material can be deposited, e.g., on one or more of the lead polymer, the sacrificial material, the nanoscale wires, etc. to form a metal lead or other conductive pathway. More than one metal can be used, which may be deposited as one or more layers. For example, a first metal may be deposited, e.g., on one or more of the lead polymers, and a second metal may be deposited on at least a portion of the first metal. Optionally, more metals can be used, e.g., a third metal may be deposited on at least a portion of the second metal, and the third metal may be the same or different from the first metal. In some cases, each metal may independently have a thickness of less than about 5 micrometers, less than about 4 micrometers, less than about 3 micrometers, less than about 2 micrometers, less than about 1 micrometer, less than about 900 nm, less than about 800 nm, less than about 700 nm, less than about 600 nm, less than about 500 nm, less than about 400 nm, less than about 300 nm, less than about 200 nm, less than about 100 nm, less than about 80 nm, less than about 60 nm, less than about 40 nm, less than about 30 nm, less than about 20 nm, less than about 10 nm, less than about 8 nm, less than about 6 nm, less than about 4 nm, or less than about 2 nm, etc., and the layers may be of the same or different thicknesses.

Any suitable technique can be used for depositing metals, and if more than one metal is used, the techniques for depositing each of the metals may independently be the same or different. For example, in one set of embodiments, deposition techniques such as sputtering can be used. Other examples include, but are not limited to, physical vapor deposition, vacuum deposition, chemical vapor deposition, cathodic arc deposition, evaporative deposition, e-beam PVD, pulsed laser deposition, ion-beam sputtering, reactive sputtering, ion-assisted deposition, high-target-utilization sputtering, high-power impulse magnetron sputtering, gas flow sputtering, or the like.

The metals can be chosen in some cases such that the deposition process yields a pre-stressed arrangement, e.g., due to atomic lattice mismatch, which causes the subsequent metal leads to warp or bend, for example, once released from the substrate. Although such processes were typically undesired in the prior art, in certain embodiments of the present invention, such pre-stressed arrangements may be used to cause the resulting 3-dimensional structure, in some cases spontaneously, upon release from the substrate. However, it should be understood that in other embodiments, the metals may not necessary be deposited in a pre-stressed arrangement.

Examples of metals that can be deposited (stressed or unstressed) include, but are not limited to, aluminum, gold, silver, copper, molybdenum, tantalum, titanium, nickel, tungsten, chromium, palladium, as well as any combinations of these and/or other metals. For example, a chromium/palladium/chromium deposition process, in some embodiments, may form a pre-stressed arrangement that is able to spontaneously form a 3-dimensional structure after release from the substrate.

In certain embodiments, a “coating” polymer can be deposited, e.g., on at least some of the conductive pathways and/or at least some of the nanoscale wires. The coating polymer may include one or more polymers, which may be deposited as one or more layers. In some embodiments, the coating polymer may be deposited on one or more portions of a substrate, e.g., as a layer of material such that portions of the coating polymer can be subsequently removed, e.g., using lithographic techniques such as e-beam lithography, photolithography, X-ray lithography, extreme ultraviolet lithography, ion projection lithography, etc., or using other techniques for removing polymer that are known to those of ordinary skill in the art, similar to the other polymers previously discussed. The coating polymers can be the same or different from the lead polymers and/or the bedding polymers. In some cases, more than one coating polymer may be used, e.g., deposited as more than one layer (e.g., sequentially), and each layer may independently have a thickness of less than about 5 micrometers, less than about 4 micrometers, less than about 3 micrometers, less than about 2 micrometers, less than about 1 micrometer, less than about 900 nm, less than about 800 nm, less than about 700 nm, less than about 600 nm, less than about 500 nm, less than about 400 nm, less than about 300 nm, less than about 200 nm, less than about 100 nm, etc. Any suitable polymer may be used as the coating polymer. For example, in one set of embodiments, one or more of the polymers may comprise poly(methyl methacrylate). In certain embodiments, one or more of the coating polymers may comprise a photoresist, e.g., SU-8, or other polymers as discussed herein.

In certain embodiments, one or more of the coating polymers can be heated or baked, e.g., before or after depositing nanoscale wires thereon as discussed below, and/or before or after patterning the coating polymer. For example, such heating or baking, in some cases, is important to prepare the polymer for lithographic patterning. In various embodiments, the coating polymer may be heated to a temperature of at least about 30° C., at least about 65° C., at least about 95° C., at least about 150° C., or at least about 180° C., etc.

Some or all of the sacrificial material may then be removed in some cases. In one set of embodiments, for example, at least a portion of the sacrificial material is exposed to an etchant able to remove the sacrificial material. For example, if the sacrificial material is a metal such as nickel, a suitable etchant (for example, a metal etchant such as a nickel etchant, acetone, etc.) can be used to remove the sacrificial metal. Many such etchants may be readily obtained commercially. In addition, in some embodiments, the structure can also be dried, e.g., in air (e.g., passively), by using a heat source, by using a critical point dryer, etc.

In certain embodiments, upon removal of the sacrificial material, pre-stressed portions of the structure (e.g., metal leads containing dissimilar metals) can spontaneously cause the structure to adopt a 3-dimensional structure or configuration. The three-dimensional structure may have a free volume of at least about 30%, at least about 40%, at least about 50%, at least about 60%, at least about 70%, at least about 75%, at least about 80%, at least about 85%, at least about 90%, at least about 95%, at least about 97, at least about 99%, at least about 99.5%, or at least about 99.8%. The three-dimensional structure may also have, in some cases, an average pore size of at least about 100 micrometers, at least about 200 micrometers, at least about 300 micrometers, at least about 400 micrometers, at least about 500 micrometers, at least about 600 micrometers, at least about 700 micrometers, at least about 800 micrometers, at least about 900 micrometers, or at least about 1 mm, and/or an average pore size of no more than about 1.5 mm, no more than about 1.4 mm, no more than about 1.3 mm, no more than about 1.2 mm, no more than about 1.1 mm, no more than about 1 mm, no more than about 900 micrometers, no more than about 800 micrometers, no more than about 700 micrometers, no more than about 600 micrometers, or no more than about 500 micrometers, etc.

However, in other embodiments, further manipulation may be needed to cause the structure to adopt a 3-dimensional structure or configuration, e.g., one with properties such as is discussed herein. For example, after removal of the sacrificial material, the structure may need to be rolled, curled, folded, creased, etc., or otherwise manipulated to form the 3-dimensional structure. Such manipulations can be done using any suitable technique, e.g., manually, or using a machine.

Other materials may be also added to the structure, e.g., before or after it forms a 3-dimensional structure, for example, to help stabilize the structure, to cause it to form a suitable 3-dimension structure, to control pore sizes, etc. A variety of materials may be used, in various embodiments of the invention. Examples of suitable materials include polymers, metals, etc., and/or combinations of these and/or other materials.

The materials may be added in a variety of forms. For example, the three-dimensional structure may be formed into a roll or tube (or other suitable shape) containing a relatively hollow cavity or portion, through which one or other materials may be added, e.g., as a solid, or as a liquid, etc. In some cases, the three-dimensional structure may also be relatively porous, e.g., defining one or more holes or pores. Materials may also be inserted or flow into such holes or pores in certain embodiments. In one set of embodiments, a solid material may be inserted into the three-dimensional structure, or a liquid material may flow through the three-dimensional structure, e.g., flowing through a channel containing the three-dimensional structure. In addition, in some embodiments, a fluid material may be added to the three-dimensional structure, and caused to solidify or polymerize, e.g., to form a solid material. Such solidification or polymerization may be initiated, for example, through a temperature change, exposure to an initiator, exposure to ultraviolet radiation, or the like, and/or any combinations of these and or other suitable techniques. In some cases, the solid material may embed all, or a portion of, the three-dimensional structure, depending on the application.

In addition, the three-dimensional structure can be interfaced in some embodiments with one or more electronics, e.g., an external electrical system such as a computer or a transmitter (for instance, a radio transmitter, a wireless transmitter, etc.). In some cases, electronic testing of the three-dimensional structure may be performed, e.g., before or after implantation into a subject. For instance, one or more of the metal leads may be connected to an external electrical circuit, e.g., to electronically interrogate or otherwise determine the electronic state or one or more of the nanoscale wires within the three-dimensional structure. Such determinations may be performed quantitatively and/or qualitatively, depending on the application, and can involve all, or only a subset, of the nanoscale wires contained within the three-dimensional structure, e.g., as discussed herein.

Accordingly, certain aspects of the invention are generally directed to articles containing sensors, e.g., comprising nanoscale wires, embedded within the article. In some cases, as discussed herein, the sensors may be present within the article at relatively high resolutions, e.g., at resolutions of less than about 2 mm, less than about 1 mm, less than about 500 micrometers, less than about 300 micrometers, less than about 100 micrometers, less than about 50 micrometers, less than about 30 micrometers, or less than about 10 micrometers. In some cases, the article may also comprise one or more conductive pathways that can be interfaced or connected to an external system, such as a computer, a transmitter, a receiver, etc., that can be used to determine one or more of the sensors or nanoscale wires, and/or in some cases, to apply electrical stimuli to one or more nanoscale wires.

The article may be any of a wide variety of articles, e.g., comprising materials such as metals, polymers, fibers, or the like. For instance, a three-dimensional networks or structures comprising nanoscale wires may be incorporated or embedded within a polymer or a metal, etc., and used to form an article. The sensors may then be used to determine a condition of the article or of a user using the article. For instance, the sensors may be used to determine mechanical strain experienced by the article, temperatures experienced by the article, chemicals that the article is exposed to, or the like. In some cases, the sensors may be used to determine a condition of a user of the article, e.g., determining sweat (e.g., by determining a change in pH), changes in body temperature (e.g., by determining a change in resistivity), or the like.

As a non-limiting example, the article may be an article of clothing or footwear. For example, a fiber or a rubber comprising three-dimensional networks or structures comprising nanoscale wires may formed into an article of clothing or footwear. Other non-limiting examples include protective articles such as helmets, body armor, or the like. For example, strains experienced by such protective articles may be determined, e.g., using such sensors, to determine the condition of the user, the suitability of the article for protection, or the like.

In one aspect, the present invention is generally directed to a fluidic channel containing a three-dimensional network or structure. For example, the network or structure may be formed into a portion of a wall defining the fluidic channel. In some cases, the channels may be microfluidic channels, but in certain instances, not all of the channels are microfluidic. There can be any number of channels, including microfluidic channels, within the device, and the channels may be arranged in any suitable configuration. The channels may independently be straight, curved, bent, etc. In some cases, a relatively large length of channels may be present in the device. For example, in some embodiments, the channels within a device, when added together, can have a total length of at least about 100 micrometers, at least about 300 micrometers, at least about 500 micrometers, at least about 1 mm, at least about 3 mm, at least about 5 mm, at least about 10 mm, at least about 30 mm, at least 50 mm, at least about 100 mm, at least about 300 mm, at least about 500 mm, at least about 1 m, at least about 2 m, or at least about 3 m in some cases.

“Microfluidic,” as used herein, refers to an article or device including at least one fluid channel having a cross-sectional dimension of less than about 1 mm. The “cross-sectional dimension” of the channel is measured perpendicular to the direction of net fluid flow within the channel. Thus, for example, some or all of the fluid channels in a device can have a maximum cross-sectional dimension less than about 2 mm, and in certain cases, less than about 1 mm. In one set of embodiments, all fluid channels in a device are microfluidic and/or have a largest cross sectional dimension of no more than about 2 mm or about 1 mm. In certain embodiments, the fluid channels may be formed in part by a single component (e.g. an etched substrate or molded unit). Of course, larger channels, tubes, chambers, reservoirs, etc. can be used to store fluids and/or deliver fluids to various elements or devices in other embodiments of the invention, for example. In one set of embodiments, the maximum cross-sectional dimension of the channels in a device is less than 500 micrometers, less than 200 micrometers, less than 100 micrometers, less than 50 micrometers, or less than 25 micrometers.

A “channel,” as used herein, means a feature on or in a device or substrate that at least partially directs flow of a fluid. The channel can have any cross-sectional shape (circular, oval, triangular, irregular, square, or rectangular, or the like) and can be covered or uncovered. In embodiments where it is completely covered, at least one portion of the channel can have a cross-section that is completely enclosed, or the entire channel may be completely enclosed along its entire length with the exception of its inlets and/or outlets or openings. A channel may also have an aspect ratio (length to average cross sectional dimension) of at least 2:1, more typically at least 3:1, 4:1, 5:1, 6:1, 8:1, 10:1, 15:1, 20:1, or more. An open channel generally will include characteristics that facilitate control over fluid transport, e.g., structural characteristics (an elongated indentation) and/or physical or chemical characteristics (hydrophobicity vs. hydrophilicity) or other characteristics that can exert a force (e.g., a containing force) on a fluid. The fluid within the channel may partially or completely fill the channel. In some cases where an open channel is used, the fluid may be held within the channel, for example, using surface tension (i.e., a concave or convex meniscus).

The channel may be of any size, for example, having a largest dimension perpendicular to net fluid flow of less than about 5 mm or 2 mm, or less than about 1 mm, less than about 500 micrometers, less than about 200 micrometers, less than about 100 micrometers, less than about 60 micrometers, less than about 50 micrometers, less than about 40 micrometers, less than about 30 micrometers, less than about 25 micrometers, less than about 10 micrometers, less than about 3 micrometers, less than about 1 micrometer, less than about 300 nm, less than about 100 nm, less than about 30 nm, or less than about 10 nm. In some cases, the dimensions of the channel are chosen such that fluid is able to freely flow through the device or substrate. The dimension of the channel may also be chosen, for example, to allow a certain volumetric or linear flow rate of fluid in the channel. Of course, the number of channels and the shape of the channels can be varied by any method known to those of ordinary skill in the art. In some cases, more than one channel may be used. For example, two or more channels may be used, where they are positioned adjacent or proximate to each other, positioned to intersect with each other, etc.

In certain embodiments, one or more of the channels within the device may have an average cross-sectional dimension of less than about 10 cm. In certain instances, the average cross-sectional dimension of the channel is less than about 5 cm, less than about 3 cm, less than about 1 cm, less than about 5 mm, less than about 3 mm, less than about 1 mm, less than 500 micrometers, less than 200 micrometers, less than 100 micrometers, less than 50 micrometers, or less than 25 micrometers. The “average cross-sectional dimension” is measured in a plane perpendicular to net fluid flow within the channel. If the channel is non-circular, the average cross-sectional dimension may be taken as the diameter of a circle having the same area as the cross-sectional area of the channel. Thus, the channel may have any suitable cross-sectional shape, for example, circular, oval, triangular, irregular, square, rectangular, quadrilateral, or the like. In some embodiments, the channels are sized so as to allow laminar flow of one or more fluids contained within the channel to occur.

The channel may also have any suitable cross-sectional aspect ratio. The “cross-sectional aspect ratio” is, for the cross-sectional shape of a channel, the largest possible ratio (large to small) of two measurements made orthogonal to each other on the cross-sectional shape. For example, the channel may have a cross-sectional aspect ratio of less than about 2:1, less than about 1.5:1, or in some cases about 1:1 (e.g., for a circular or a square cross-sectional shape). In other embodiments, the cross-sectional aspect ratio may be relatively large. For example, the cross-sectional aspect ratio may be at least about 2:1, at least about 3:1, at least about 4:1, at least about 5:1, at least about 6:1, at least about 7:1, at least about 8:1, at least about 10:1, at least about 12:1, at least about 15:1, or at least about 20:1.

As mentioned, the channels can be arranged in any suitable configuration within the device. Different channel arrangements may be used, for example, to manipulate fluids, droplets, and/or other species within the channels. For example, channels within the device can be arranged to create droplets (e.g., discrete droplets, single emulsions, double emulsions or other multiple emulsions, etc.), to mix fluids and/or droplets or other species contained therein, to screen or sort fluids and/or droplets or other species contained therein, to split or divide fluids and/or droplets, to cause a reaction to occur (e.g., between two fluids, between a species carried by a first fluid and a second fluid, or between two species carried by two fluids to occur), or the like.

Fluids may be delivered into channels within a device via one or more fluid sources. Any suitable source of fluid can be used, and in some cases, more than one source of fluid is used. For example, a pump, gravity, capillary action, surface tension, electroosmosis, centrifugal forces, etc. may be used to deliver a fluid from a fluid source into one or more channels in the device. Non-limiting examples of pumps include syringe pumps, peristaltic pumps, pressurized fluid sources, or the like. The device can have any number of fluid sources associated with it, for example, 1, 2, 3, 4, 5, 6, 7, 8, 9, 10, etc., or more fluid sources. The fluid sources need not be used to deliver fluid into the same channel, e.g., a first fluid source can deliver a first fluid to a first channel while a second fluid source can deliver a second fluid to a second channel, etc. In some cases, two or more channels are arranged to intersect at one or more intersections. There may be any number of fluidic channel intersections within the device, for example, 2, 3, 4, 5, 6, etc., or more intersections.

A variety of materials and methods, according to certain aspects of the invention, can be used to form devices or components such as those described herein, e.g., channels such as microfluidic channels, chambers, etc. For example, various devices or components can be formed from solid materials, in which the channels can be formed via micromachining, film deposition processes such as spin coating and chemical vapor deposition, laser fabrication, photolithographic techniques, etching methods including wet chemical or plasma processes, and the like. See, for example, Scientific American, 248:44-55, 1983 (Angell, et al).

In one set of embodiments, various structures or components of the devices described herein can be formed of a polymer, for example, an elastomeric polymer such as polydimethylsiloxane (“PDMS”), polytetrafluoroethylene (“PTFE” or Teflon®), or the like. For instance, according to one embodiment, a microfluidic channel may be implemented by fabricating the fluidic device separately using PDMS or other soft lithography techniques (details of soft lithography techniques suitable for this embodiment are discussed in the references entitled “Soft Lithography,” by Younan Xia and George M. Whitesides, published in the Annual Review of Material Science, 1998, Vol. 28, pages 153-184, and “Soft Lithography in Biology and Biochemistry,” by George M. Whitesides, Emanuele Ostuni, Shuichi Takayama, Xingyu Jiang and Donald E. Ingber, published in the Annual Review of Biomedical Engineering, 2001, Vol. 3, pages 335-373; each of these references is incorporated herein by reference).

Other examples of potentially suitable polymers include, but are not limited to, polyethylene terephthalate (PET), polyacrylate, polymethacrylate, polycarbonate, polystyrene, polyethylene, polypropylene, polyvinylchloride, cyclic olefin copolymer (COC), polytetrafluoroethylene, a fluorinated polymer, a silicone such as polydimethylsiloxane, polyvinylidene chloride, bis-benzocyclobutene (“BCB”), a polyimide, a fluorinated derivative of a polyimide, or the like. Combinations, copolymers, or blends involving polymers including those described above are also envisioned. The device may also be formed from composite materials, for example, a composite of a polymer and a semiconductor material.

In some embodiments, various structures or components of the device are fabricated from polymeric and/or flexible and/or elastomeric materials, and can be conveniently formed of a hardenable fluid, facilitating fabrication via molding (e.g. replica molding, injection molding, cast molding, etc.). The hardenable fluid can be essentially any fluid that can be induced to solidify, or that spontaneously solidifies, into a solid capable of containing and/or transporting fluids contemplated for use in and with the fluidic network. In one embodiment, the hardenable fluid comprises a polymeric liquid or a liquid polymeric precursor (i.e. a “prepolymer”). Suitable polymeric liquids can include, for example, thermoplastic polymers, thermoset polymers, waxes, metals, or mixtures or composites thereof heated above their melting point. As another example, a suitable polymeric liquid may include a solution of one or more polymers in a suitable solvent, which solution forms a solid polymeric material upon removal of the solvent, for example, by evaporation. Such polymeric materials, which can be solidified from, for example, a melt state or by solvent evaporation, are well known to those of ordinary skill in the art. A variety of polymeric materials, many of which are elastomeric, are suitable, and are also suitable for forming molds or mold masters, for embodiments where one or both of the mold masters is composed of an elastomeric material. A non-limiting list of examples of such polymers includes polymers of the general classes of silicone polymers, epoxy polymers, methacrylate polymer, and other acrylate polymers. Epoxy polymers are characterized by the presence of a three-membered cyclic ether group commonly referred to as an epoxy group, 1,2-epoxide, or oxirane. For example, diglycidyl ethers of bisphenol A can be used, in addition to compounds based on aromatic amine, triazine, and cycloaliphatic backbones. Another example includes the well-known Novolac polymers. Non-limiting examples of silicone elastomers suitable for use according to the invention include those formed from precursors including the chlorosilanes such as methylchlorosilanes, ethylchlorosilanes, phenylchlorosilanes, etc. Silicone polymers are used in certain embodiments, for example, the silicone elastomer polydimethylsiloxane. Non-limiting examples of PDMS polymers include those sold under the trademark Sylgard by Dow Chemical Co., Midland, Mich., and particularly Sylgard 182, Sylgard 184, and Sylgard 186. Silicone polymers including PDMS have several beneficial properties simplifying fabrication of various structures of the invention. For instance, such materials are inexpensive, readily available, and can be solidified from a prepolymeric liquid via curing with heat. For example, PDMSs are typically curable by exposure of the prepolymeric liquid to temperatures of about, for example, about 65° C. to about 75° C. for exposure times of, for example, about an hour. Also, silicone polymers, such as PDMS, can be elastomeric and thus may be useful for forming very small features with relatively high aspect ratios, necessary in certain embodiments of the invention. Flexible (e.g., elastomeric) molds or masters can be advantageous in this regard.

One advantage of forming structures such as microfluidic structures or channels from silicone polymers, such as PDMS, is the ability of such polymers to be oxidized, for example by exposure to an oxygen-containing plasma such as an air plasma, so that the oxidized structures contain, at their surface, chemical groups capable of cross-linking to other oxidized silicone polymer surfaces or to the oxidized surfaces of a variety of other polymeric and non-polymeric materials. Thus, structures can be fabricated and then oxidized and essentially irreversibly sealed to other silicone polymer surfaces, or to the surfaces of other substrates reactive with the oxidized silicone polymer surfaces, without the need for separate adhesives or other sealing means. In most cases, sealing can be completed simply by contacting an oxidized silicone surface to another surface without the need to apply auxiliary pressure to form the seal. That is, the pre-oxidized silicone surface acts as a contact adhesive against suitable mating surfaces. Specifically, in addition to being irreversibly sealable to itself, oxidized silicone such as oxidized PDMS can also be sealed irreversibly to a range of oxidized materials other than itself including, for example, glass, silicon, silicon oxide, quartz, silicon nitride, polyethylene, polystyrene, glassy carbon, and epoxy polymers, which have been oxidized in a similar fashion to the PDMS surface (for example, via exposure to an oxygen-containing plasma). Oxidation and sealing methods useful in the context of the present invention, as well as overall molding techniques, are described in the art, for example, in an article entitled “Rapid Prototyping of Microfluidic Devices and Polydimethylsiloxane,” Anal. Chem., 70:474-480, 1998 (Duffy et al.), incorporated herein by reference.

The following documents are incorporated herein by reference: U.S. Pat. No. 7,211,464, issued May 1, 2007, entitled “Doped Elongated Semiconductors, Growing Such Semiconductors, Devices Including Such Semiconductors, and Fabricating Such Devices,” by Lieber, et al.; U.S. Pat. No. 7,301,199, issued Nov. 27, 2007, entitled “Nanoscale Wires and Related Devices,” by Lieber, et al.; and International Patent Application No. PCT/US2010/050199, filed Sep. 24, 2010, entitled “Bent Nanowires and Related Probing of Species,” by Tian, et al., published as WO 2011/038228 on Mar. 31, 2011. Also incorporated herein by reference in their entireties are U.S. Prov. Pat. Apl. Ser. No. 61/698,492, entitled “Methods And Systems For Scaffolds Comprising Nanoelectronic Components,” filed Sep. 7, 2012; U.S. Prov. Pat. Apl. Ser. No. 61/698,502, entitled “Scaffolds Comprising Nanoelectronic Components For Cells, Tissues, And Other Applications,” filed Sep. 7, 2012; U.S. Provisional Patent Application Ser. No. 61/723,213, filed Nov. 6, 2012, entitled “Methods And Systems For Scaffolds Comprising Nanoelectronic Components,” by Lieber, et al. and U.S. Provisional Patent Application Ser. No. 61/723,222, filed Nov. 6, 2012, entitled “Scaffolds Comprising Nanoelectronic Components For Cells, Tissues, And Other Applications,” by, Lieber, et al. Also incorporated herein by reference is U.S. Provisional Patent Application Ser. No. 61/809,220, filed Apr. 5, 2013, entitled “Three-Dimensional Networks Comprising Nanoelectronics,” by Lieber, et al.

The following examples are intended to illustrate certain embodiments of the present invention, but do not exemplify the full scope of the invention.

### Example 1

The following examples describe a general strategy for 3D integration of electronics with host materials based on regular arrays of addressable nanowire nanoelectronic elements within 3D macroporous nanoelectronic networks, and also show how these networks can be used to map chemical and mechanical changes induced by the external environment in 3D.

This example describes a “bottom-up” approach for realizing 3D macroporous nanoelectronic networks and their incorporation into host materials as outlined schematically in FIG. 1. In this approach, functional nanowire nanoelectronic elements are used (FIG. 1A). In some cases, variations in composition, morphology, doping, etc. encoded during synthesis can be used to define functionality, for example, including devices for logic and memory, sensors, light-emitting diodes, energy production and storage, etc. The macroporous nanoelectronic network with nanowire elements (FIG. 1B) is realized through a combination of nanowire assembly and conventional 2D lithography carried out on a sacrificial substrate, as discussed below. Removal of the sacrificial layer yields a free-standing and flexible 2D macroporous nanoelectronic networks (FIG. 1B). The 2D macroporous nanoelectronic networks may be organized into 3D macroporous structures, for example, by self- or directed-assembly, and then merged within host material samples (FIG. 1C). For example, the merger may occur using a solution (or liquid) casting process at or near room temperature, or via other techniques.

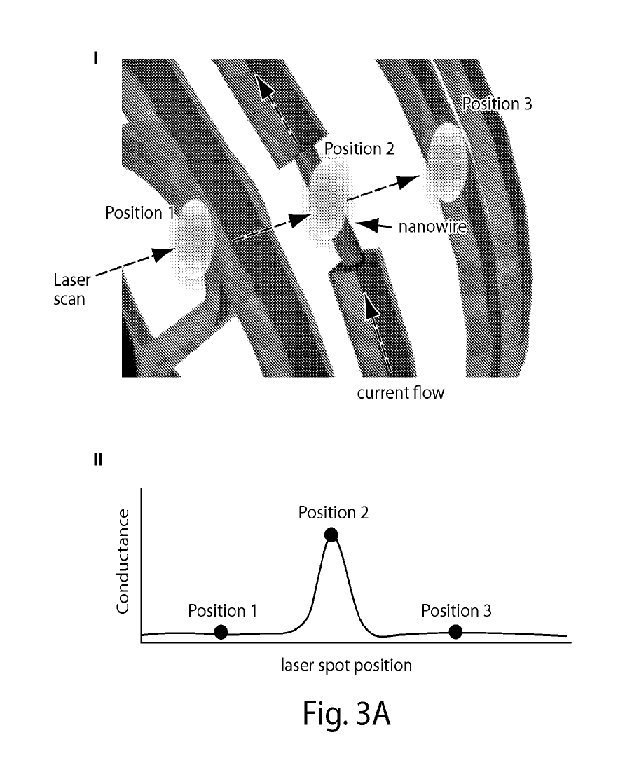

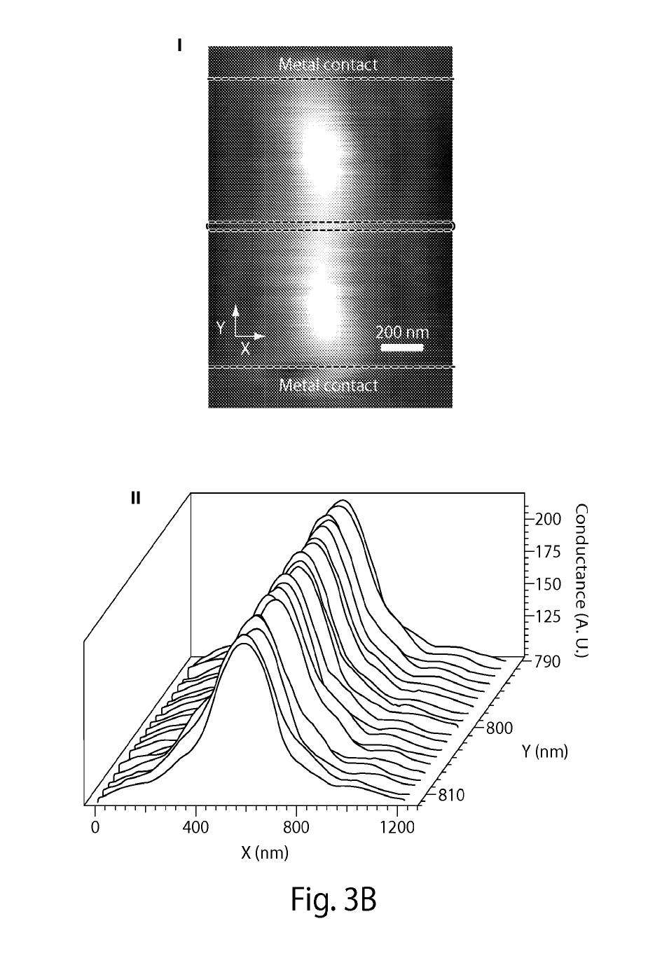

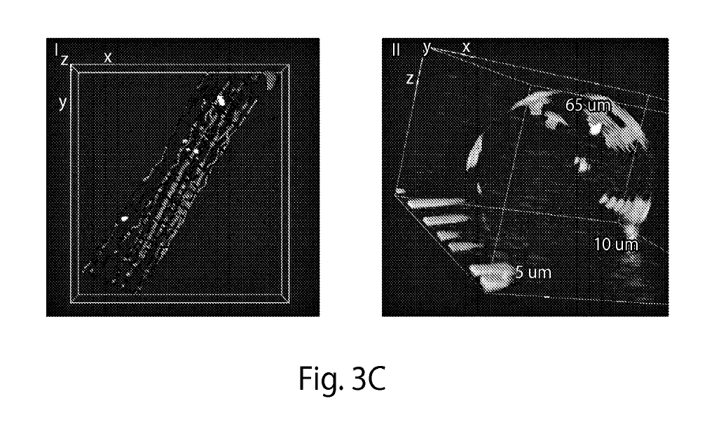

FIG. 1 shows various strategies for preparing 3D macroporous nanoelectronic networks and integration with host materials. FIG. 1A shows different nanowire nanoelectronic elements (from left to right): kinked nanowire, nanotube, core-shell, straight and branched nanowire. FIG. 1B shows a free-standing 2D macroporous nanowire nanoelectronic “precursor,” including nanoelectronic elements, passivation polymers, metal contacts, and input/output (I/O). FIG. 3D shows macroporous nanoelectronic networks integrated with host materials.

Various steps involved in the fabrication, 3D organization and characterization of the macroporous nanoelectronic networks are outlined in FIG. 2. Additional details are provided below. Briefly, first, nanowires were uniaxially-aligned by contact printing on the surface of a layer of SU-8 negative resist, where the SU-8 was deposited by spin-coating on a Ni sacrificial layer deposited on a carrier substrate (FIG. 2A, I). Second, the SU-8 layer with aligned nanowires was patterned to define a periodic array by photolithography or electron beam lithography (EBL), and the excess nanowires on unexposed regions of the SU-8 were removed when the pattern was developed (FIG. 2A, II). The nanowire density and feature size in periodic arrays were chosen in this example such that each element contained on average 1-2 nanowires, although other densities or sizes may be chosen in other embodiments. Third, a second SU-8 layer was deposited and patterned in a mesh structure by lithography (FIG. 2A, III). This SU-8 mesh served to interconnect the nanowire/SU-8 periodic features and provides an adjustable support structure to tune the mechanical properties. Fourth, metal interconnects were defined by standard lithography and metal deposition on top of the appropriate regions of the SU-8 mesh, such that the end of nanowires were contacted and the nanowire elements were independently addressable (FIG. 2A, IV). Last, a third SU-8 layer was lithographically patterned to cover and passivate the metal interconnects.

Dark-field optical microscopy images obtained from a typical nanoelectronic mesh fabrication corresponding to the steps described above (FIG. 2B, I-IV) highlight several features. First, the images recorded after contact printing (FIG. 2B, I) confirm that nanowires were well-aligned over areas where nanowire devices are fabricated. Good nanowire alignment was achieved on length scales up to at least several centimeters. Second, a representative dark-field image of the patterned periodic nanowire regions (FIG. 2B, II) showed that this process removed nearly all of the nanowires outside of the desired features. Nanowires were observed to extend outside of the periodic circular feature (i.e., an end is fixed at the feature) at some points; however, these were infrequent and did not affect subsequent steps defining the nanodevice interconnections. Third, images of the underlying SU-8 mesh (FIG. 2B, III) and the final device network with SU-8 passivated metal contacts and interconnects (FIG. 2B, IV) highlighted the regular array of addressable nanowire devices realized in this particular fabrication process. Lastly, scanning electron microscopy (SEM) images (FIG. 2C) showed that these device elements had on average 1-2 nanowires in parallel, as expected.

The 2D nanoelectronic mesh structures were converted to free-standing macroporous networks by dissolution of the sacrificial Ni layers over a period of 1-2 h (see below). Representative images of a free-standing nanoelectronic network (FIG. 2D and FIG. 2E) highlighted the 3D and flexible characteristics of the structure and showed how input/output (I/O) to the free-standing network could be fixed at one end outside of a solution measurement petri-dish chamber. Electrical characterization of individually-addressable nanowire device elements in a free-standing mesh demonstrates that the device-yield was ˜90% (from 128 device design) for the free-standing nanoelectronic mesh structures fabricated in this example. The average conductance of the devices from a representative free-standing mesh (FIG. 2F), 2.85+/−1.6 microsiemens, was consistent with 1-2 nanowires/device based on measurements of similar (30 nm diameter, 2 micrometer channel length) p-type Si single nanowire devices, and thus also agreed with the structural data discussed above. In addition, by varying the printed nanowire density and S/D metal contact widths, it was possible to tune further the average number of nanowires per device element.

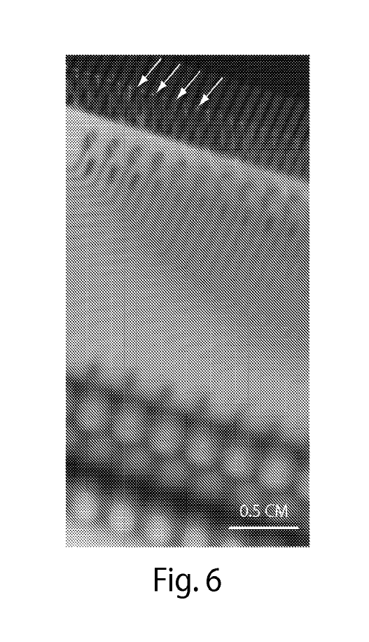

FIG. 2 shows organized 2D and 3D macroporous nanoelectronic networks. FIG. 2A illustrates schematics of nanowire registration by contact printing and SU-8 patterning. 10: Silicon wafer, 12: Ni sacrificial layer, 16: nanowire, 14: SU-8, 20: metal contact. (Top) shows top view and (bottom) shows side view. (I): Contact printing nanowire on SU-8. (II): Regular SU-8 structure was patterned by lithography to immobilize nanowires. Extra nanowires were washed away during the develop process of SU-8. (III): Regular bottom SU-8 structure was patterned by spin-coating and lithography. (IV): Regular metal contact was patterned by lithography and thermal evaporation, followed by top SU-8 passivation. FIG. 2B is a dark field optical images corresponding to each step of schematics in FIG. 2A. The nanowire and SU-8 features can be seen in these images. The small features on the right and lower edges of the image in (II) correspond to metal lithography markers used in alignment. The dashed line highlights metal contacts/interconnects in (IV), respectively. FIG. 2C is a SEM image of a 2D macroporous nanoelectronic network prior to release from the substrate. Inset corresponds to a zoom-in of the region enclosed by the dashed box containing a single nanowire device. FIG. 2D is a photograph of a wire-bonded free-standing 2D macroporous nanoelectronic network in petri-dish chamber for aqueous solution measurements. The dashed box highlights the free-standing portion of the nanoelectronic network and the smaller white-dashed box encloses the wire-bonded interface between the input/output (I/O) and PCB connector board. FIG. 2E is a zoom-in of the region enclosed by the larger dashed box in FIG. 2D. FIG. 2F is a histogram nanowire device conductance in the free-standing 2D macroporous nanoelectronic networks. Also, FIG. 6 shows a 2D macroporous nanoelectronic network, with a zoom-in of the region enclosed by the white-dashed box in FIG. 2D. The white arrows highlight several wire bonds.

### Example 2

In this example, the 2D free-standing macroporous nanoelectronic networks described in Example 1 were transformed to 3D structures using two general methods. First, 2D macroporous nanoelectronic networks were manually rolled-up into 3D arrays (FIG. 2G) with nanoelectronic elements in different layers of the resulting “scroll” using techniques similar to those disclosed in U.S. Provisional Patent Application Ser. No. 61/723,213, filed Nov. 6, 2012, entitled “Methods And Systems For Scaffolds Comprising Nanoelectronic Components,” by Lieber, et al. and U.S. Provisional Patent Application Ser. No. 61/723,222, filed Nov. 6, 2012, entitled “Scaffolds Comprising Nanoelectronic Components For Cells, Tissues, And Other Applications,” by Lieber, et al., each incorporated herein by reference in its entirety.

Second, by introducing built-in stress in metal interconnects with a trilayer metal stack (see below), the mesh could be designed to self-organize into a similar scrolled structure as achieved by manual rolling. A reconstructed 3D confocal fluorescent image of a 3D nanoelectronic mesh array produced in this manner (FIG. 2H) shows a 3D macroporous nanoelectronic network and can be used to estimate a free volume of (>99%). More generally, these self-organized 3D macroporous nanoelectronic structures could be readily diversified to meet goals for different hybrid materials, e.g., using mechanical design and bifurcation strategies.

FIG. 2G shows a photograph of a manually scrolled-up 3D macroporous nanoelectronic network. FIG. 2H shows a 3D reconstructed confocal fluorescence images of self-organized 3D macroporous nanoelectronic network viewed along the x-axis. Nonsymmetrical Cr/Pd/Cr metal layers (see below), which are stressed, were used to drive self-organization. The SU-8 ribbons were doped with Rodamine-6G for imaging.

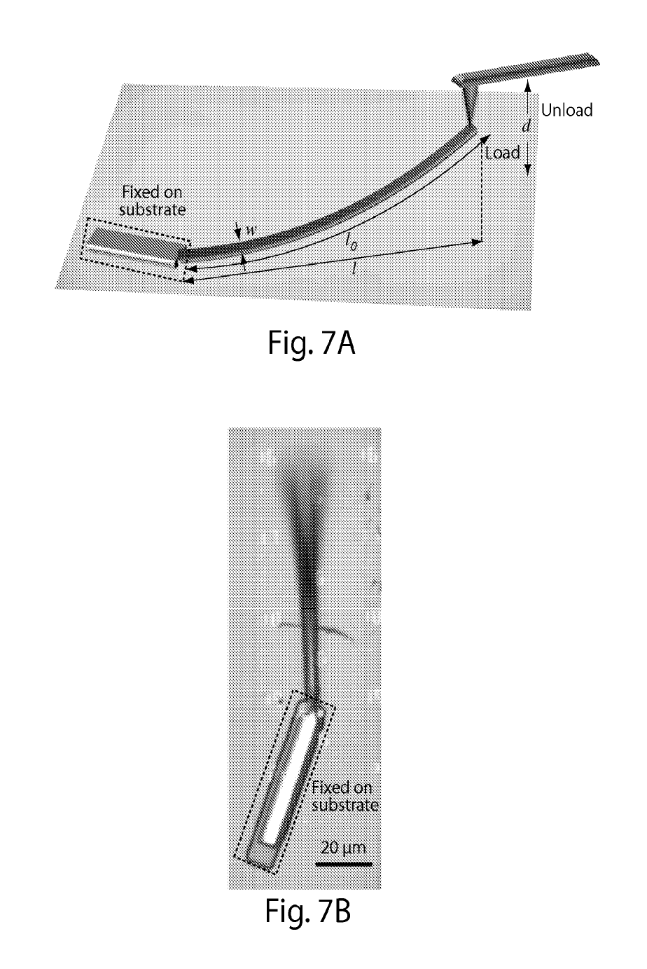

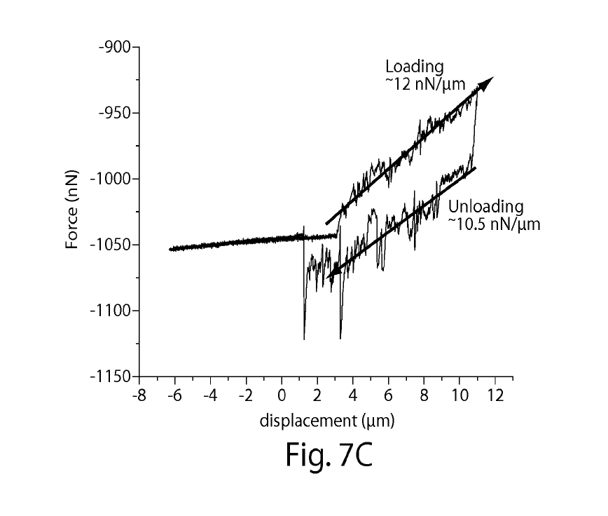

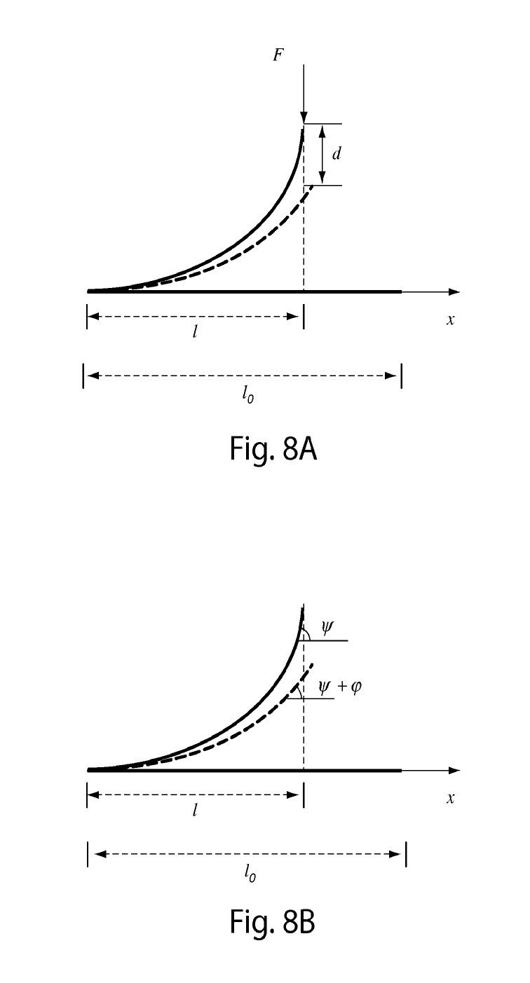

Qualitatively, the facile manipulation of the macroporous nanoelectronic networks to form 3D structures suggests a very low effective bending stiffness. The effective bending stiffness, D̅, can be evaluated using a combination of calculations and experimental measurements (see below and FIGS. 7 and 8). In short, D̅=αₛDₛ+αₘDₘ where Dₛ and Dₘ are bending stiffness per unit width for the SU-8 structural elements and SU-8/metal/SU-8 interconnects, respectively, and αₛ and αₘ are the respective area fractions for these elements in the networks. For typical 3D macroporous nanoelectronic networks, the area fraction for both types of elements (i.e., SU-8 and SU-8/metal/SU-8) can range from 1 to 10%, yielding values of the effective bending stiffness from 0.0038 to 0.0378 nN-m.

Mechanical properties. The 3D macroporous nanoelectronic networks contained single-layer polymer (SU-8) structural and three-layer ribbon (SU-8/metal/SU-8) interconnect elements. The effective bending stiffness per unit width of the 3D macroporous nanoelectronic networks could be estimated using the following equation:

D̅=αₛDₛ+αₘDₘ (1)

where αₛ and aₘ are the area fraction of the single-layer polymer and three-layer interconnect ribbons in the networks. Dₛ=Eₛh³/12 is the bending stiffness per unit width of the single-layer polymer, where Eₛ=2 GPa and h are the modulus and thickness of the SU-8. For a SU-8 ribbon with 500 nm thickness, Dₛ is 0.02 nN·m. Dₘ is the bending stiffness per unit width of a three-layer structure, which includes 500 nm lower and upper SU-8 layers and 100 to 130 nm metal layer, and was measured experimentally as shown in FIG. 7.

### Example 3

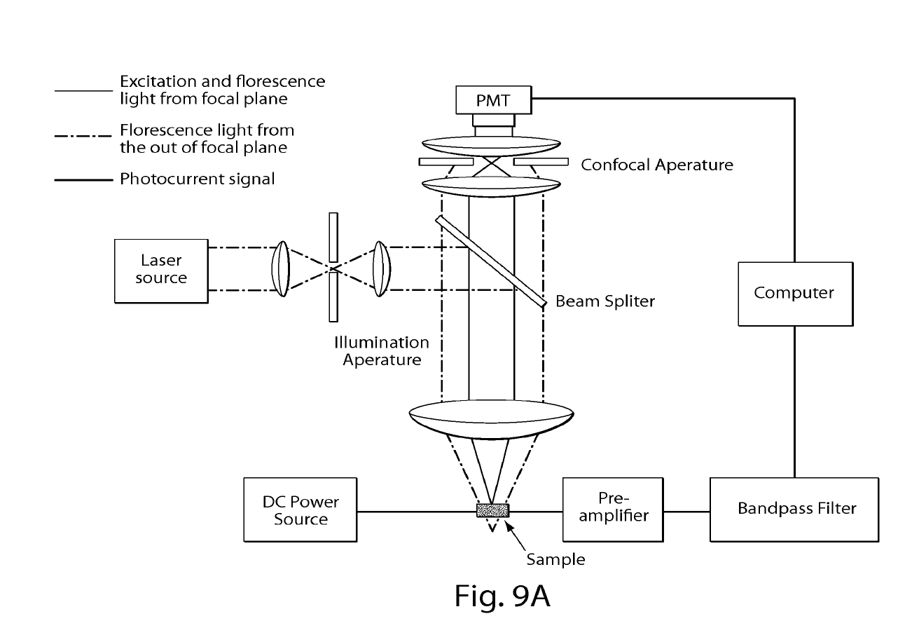

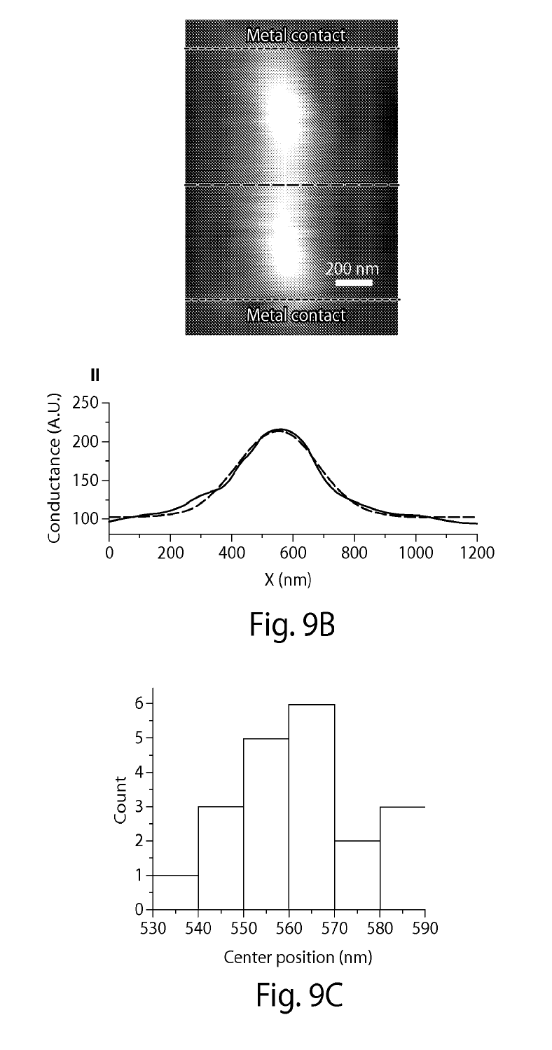

The semiconductor nanowire networks described above can display various sensory functionalities, including photon, chemical, biochemical, or potentiometric sensing, as well as strain detection, which make them particularly attractive for preparing hybrid active materials such as those described below. Photoconductivity changes (i.e., photon detection) of nanowire elements were characterized while imaging the nanoelectronic networks with a confocal microscope by recording conductance as a function of x-y-z coordinates and overlapping with simultaneously acquired fluorescence images (see below, FIG. 3A, and FIG. 9A). As the focused laser is scanned across a sample (FIG. 3A, I), an increase of conductance due to the photocurrent in the nanowire is recorded at the positions of the nanowire devices.

The resolution of this approach can be assessed in two ways. Conventionally, the plot of conductance versus position (FIG. 3A, II) can be fit with a Gaussian function and its full-width at half-maximum (FWHM) reflects the diffraction limited resolution of the illuminating light spot. Second and recognizing that the nanowire diameter (30 nm) is line-like, methods similar to super-resolution imaging technologies can be used to locate the nanowire to much higher precision by identifying the peak position from the Gaussian fit. See, e.g., U.S. Pat. No. 7,838,302, incorporated herein by reference. It is noted that a similar concept as exploited in stochastic super-resolution imaging to resolve close points could be implemented in the photoconductivity maps because individual devices can be turned on and off as needed.

A typical high-resolution photoconductivity image of a single nanowire device (FIG. 3B, I) shows the position of the nanowire. The conductance change versus x-position perpendicular to the nanowire axis (FIG. 3B, II and FIG. 9B) yielded a FWHM of 314+/−32 nm (n=20) resolution, consistent with confocal microscopy imaging resolution (202 nm) in this experiment. Moreover, the nanowire position determined from the peaks of Gaussian fits (FIG. 9C) yielded a standard deviation of 14 nm (n=20), and showed that the position of devices can be localized with a precision better than the diffraction limit. In addition, simultaneous photoconductivity and fluorescence confocal microscopy images have been acquired to map the positions of nanowire devices in 3D macroporous nanoelectronic networks. Reconstructed 3D images (FIG. 3C) showed that 12 active nanowire devices could be readily mapped with respect to x-y-z coordinated in a “rolled-up” macroporous nanoelectronic network structure. Given the complexity possible in 3D nanoelectric/host hybrid materials, this approach provides straightforward methodology for determining, at high resolutions, the positions of the active nanoelectronic sensory elements with respect to structures within the host. The resolution could be further improved by incorporating point-like transistor photoconductivity detectors, p-n photodiodes, or p-i-n avalanche photodiodes nanowire building blocks within the 3D macroporous nanoelectronic network.

FIG. 3 shows various 3D macroporous photodetectors and device localization. FIG. 3A is a schematic of the single 3D macroporous nanowire photodetector characterization. The ellipse is a laser spot; the cylinder is a nanowire and the other structures are the SU-8 mesh network. The illumination of the laser spot generated from confocal microscope on the nanowire device (I) makes the conductance change of nanowire, which could be (II) correlated with laser spot position. Spots in (II) correlate to the laser spot positions in (I). FIG. 3B is a high-resolution (1 nm per pixel) photocurrent image (I) from single nanowire device (2 micrometer channel length) on substrate recorded with focused laser spot scanned in x-y plane. The black dashed lines indicate the boundary of metal contact in the device. (II) 20 times photocurrent measurements from the central region (dashed box) of the nanowire device with high resolution (the distance for each trace in x-direction is 1 nm). FIG. 3C is a 3D reconstructed photocurrent imaging overlapped with confocal microscopy imaging shows the spatial correlation between nanowire photodetectors with SU-8 framework in 3D. Darker regions: false color of the photocurrent signal; lighter regions (rhodamine 6G): SU-8 mesh network. Dimensions in (I), x: 317 micrometers; y: 317 micrometers; z: 53 micrometers; in (II), x: 127 micrometers; y: 127 micrometers; z: 65 micrometers. The white numbers in (II) indicate the heights of the nanowire photodetectors.

FIG. 9 shows the localization of 3D macroporous nanoelectronic devices. 3D macroporous nanoelectronic FET devices exhibited photoconductivity that was used to determine spatial positions using a confocal microscope equipped with an analog signal input box. FIG. 9A shows a schematic of photocurrent detection and correlation with confocal microscopy laser spot scanning position. A 405 nm laser wavelength, 100× water immersion lens, and 0.1 mV source/drain device bias-voltage were used in the experiments. FIG. 9B shows high-resolution (1 nm per pixel) photocurrent image (I) from a single nanowire device (2 micrometer channel length between upper/lower metal contacts) recorded scanning in x-y plane. The middle dashed line indicates the direction perpendicular to the nanowire axis. The outer dashed lines indicate the boundaries of metal contacts. (II) Photocurrent measured along the middle dashed line in (I). Experimental data were fit with a Gaussian distribution (solid curve). FIG. 3C shows the distribution of the center point positions determined from the 20 independent scans in region of indicated in FIG. 3B and about the single scan line shown in FIG. 9B.

### Example 4

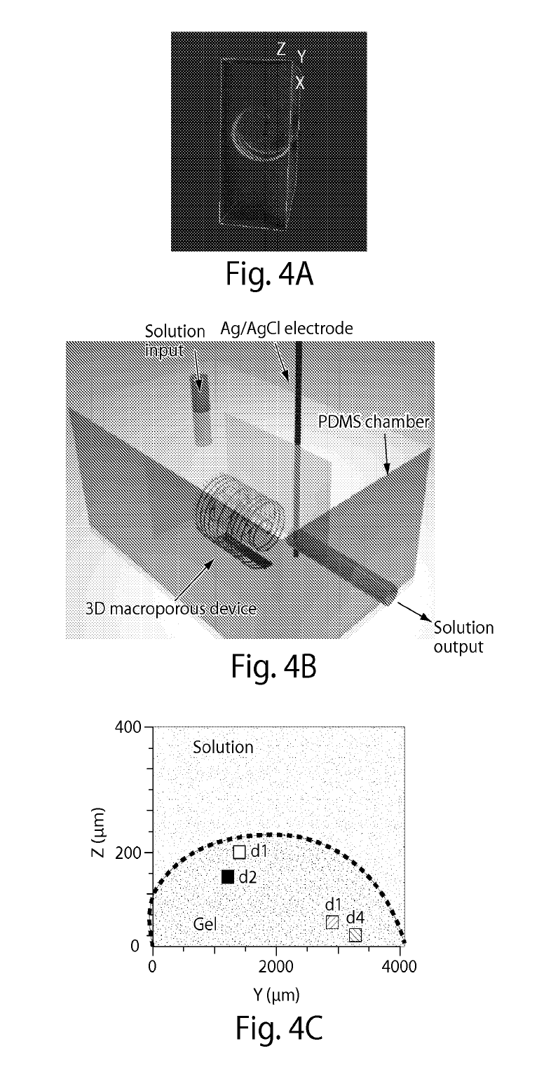

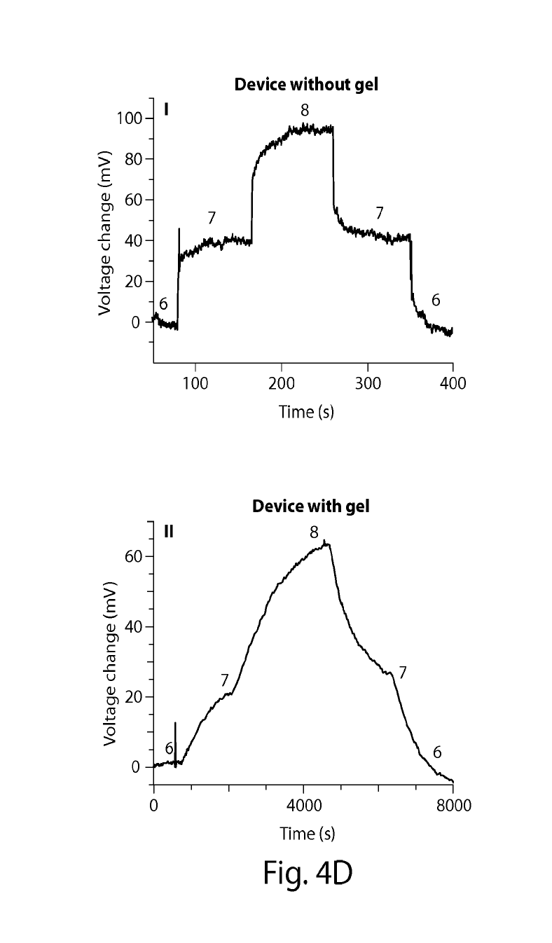

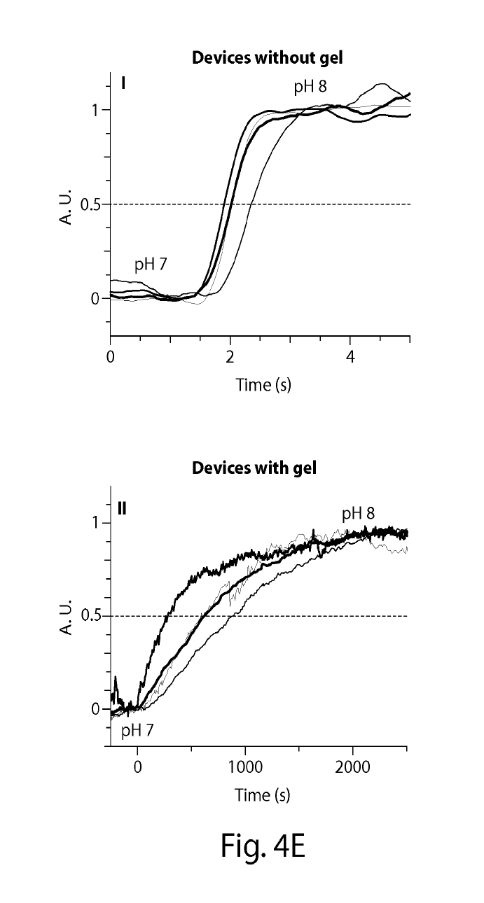

This example illustrates macroporous nanowire nanoelectronic networks that weer used to map pH changes in 3D through an agarose gel using a macroporous nanoelectronic/gel hybrid, and for comparison, in aqueous solution using a free-standing 3D nanoelectronic sensory network. The hybrid nanoelectronic/gel material was prepared by casting agarose around a rolled-up macroporous nanoelectronic network, where the gel and SU-8 mesh of the nanoelectronic network were doped with 4′,6-diamidino-2-phenylindole (DAPI) and rodamine 6G, respectively (see below). A reconstructed 3D confocal microscopy image of the hybrid material (FIG. 4A) showed a 3D device mesh fully embedded within an agarose gel block without phase separation. To carry out sensing experiments, either the 3D nanoelectronic/gel hybrid material or a 3D nanoelectronic mesh was contained within a microfluidic chamber (FIG. 4B). Positions of nanowire transistor devices, which can function as very sensitive chemical/biological detectors, were determined by the photocurrent mapping technique described above. For both 3D nanoelectronic mesh and nanoelectronic/gel hybrid, signals were recorded simultaneously from 4 devices chosen to span positions from upper to lower boundary of mesh or gel, where representative z-coordinates of the devices positions within the hybrid sample are highlighted in FIG. 4C; a similar z-range of devices for the free nanoelectronic mesh was also used.

Representative data recorded from p-type nanowire FET devices in 3D mesh network without gel (FIG. 4D, I) and in the hybrid 3D nanoelectronic mesh/agarose gel hybrid (FIG. 4D, II) highlight several important points. First, the device within 3D macroporous network without gel showed fast stepwise conductance changes (<1 s) with solution pH changes. The typical sensitivity of these devices was about 40 mV/pH, and was consistent with values reported for similar nanowire devices. Second, the device within the 3D nanoelectronic mesh/gel hybrid exhibited substantially slower transition times with corresponding changes of the solution pH; that is, signal changes required on the order of 2000 s to reach steady state, and thus was 1000-fold slower than in free solution. Third, the device within the 3D nanoelectronic mesh/gel hybrid exhibited lower pH sensitivity in terms of mV/pH, e.g., 20 to 40 mV/pH for device in gel compared to 40 to 50 mV/pH for device in free solution.

Direct comparison of the temporal responses of four devices at different 3D positions in the two types of samples (FIG. 4E) provided additional insight into the pH changes. The time to achieve one-half pH unit change for the four different devices in 3D macroporous network without gel (FIG. 4E, I) was about 0.5 s and the difference between devices was only about 0.01 s. It was noted that the time delay in the data recorded from device d4 (see FIG. 4C) was consistent with the downstream position of this device within the fluidic channel. In contrast, the time to achieve one-half for the four devices in the 3D nanoelectronic mesh/gel hybrid (FIG. 4E, II) ranged from about 280 to 890s for devices d1 to d4, respectively, where the devices were positioned as shown in FIG. 4C. The results showed that the device response time within the agarose was about 500 to 1700 times slower than in solution and was proportional to the distance from the solution/gel boundary, although the detailed variation suggested heterogeneity in the diffusion within the agarose gel. Significantly, the ability to map the diffusion of molecular and biomolecular species in 3D hybrid systems using the macroporous nanoelectronic sensory networks offers opportunities for self-monitoring of gel, polymers and tissue systems relevant to many areas of science and technology.

FIG. 4 shows various 3D macroporous chemical sensors. FIG. 4A shows x-z views of 3D reconstructed image of the 3D macroporous nanoelectronic network in gel, including an SU-8 mesh network and agrose gel. Dimensions: x=317 micrometers; y=317 micrometers; and z=144 micrometers. FIG. 4B is a schematic of the experimental set-up. FIG. 4C shows the projection of four nanowire devices in the y-z plane. Dashed line corresponds to the approximate gel boundary, and the aqueous solution and agrose gel regions are marked accordingly. FIG. 4D shows representative changes in calibrated voltage over time with pH change for 3D macroporous nanowire chemical sensors (I) in solution (I) and (II) embedded in agrose gel. FIG. 4E shows calibrated voltage with one pH value change in solution for 4 different devices located in 3D space. (I) 4 devices without gel and (II) 4 devices embedded in agrose gel.

### Example 5

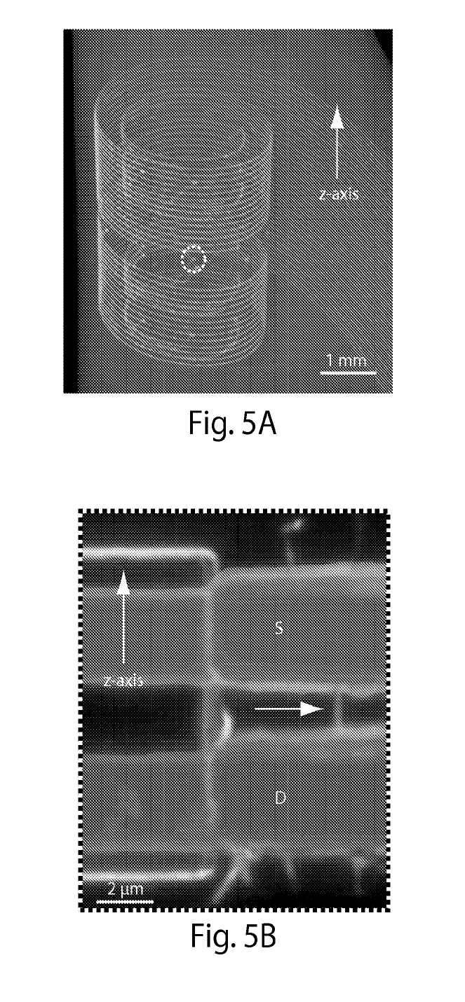

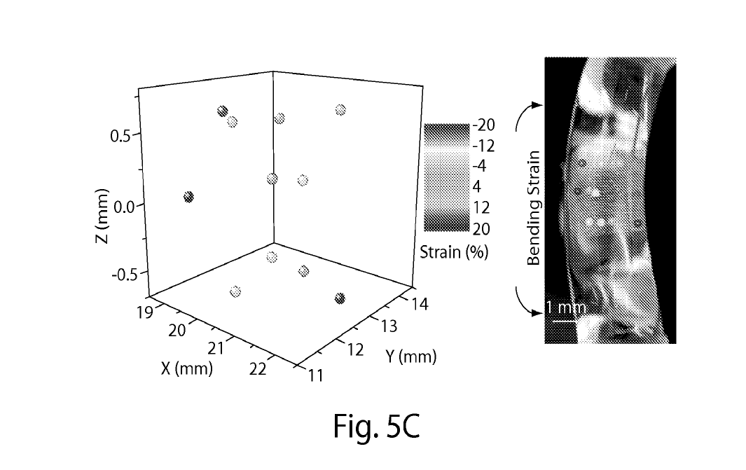

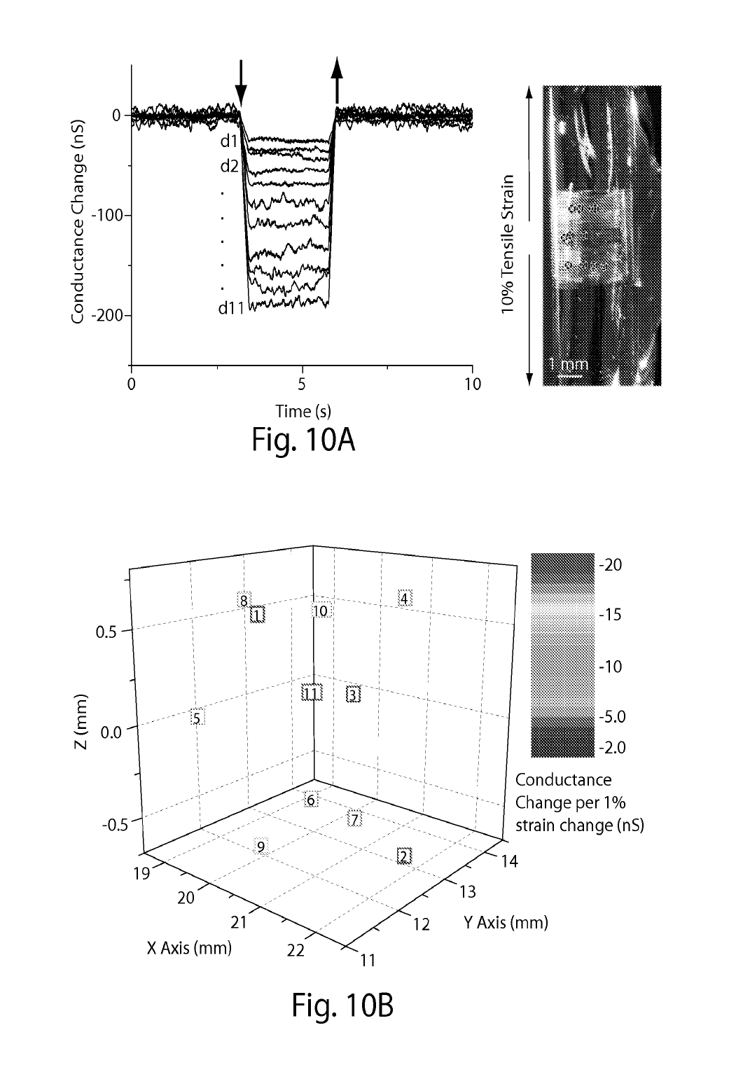

This example illustrates embedded 3D macroporous nanoelectronic networks that were used to map strain distributions in elastomeric silicone host materials. Si nanowires have a high piezoresistance response, making them good candidates for strain sensors. To explore the potential of Si nanowire device arrays to map strain within materials, in this example, 3D macroporous nanoelectronic network/elastomer hybrid materials have prepared and characterized (see below). The resulting hybrid macroporous nanoelectronic network/elastomer cylinders had volumes of about 300 mm³ with volume ratio of device/elastomer of <0.1%. X-ray micro-computed tomography (μCT) studies of the nanoelectronic network/elastomer cylinders (FIG. 5A and FIG. 10) were used to determine the 3D metal interconnects and locations of nanowire devices within the cylindrical hybrid structures (see below). The alignment of nanowire elements along the cylinder axis was confirmed by dark-field optical microscopy images (FIG. 5B), which show the nanowires lying along the cylinder (z) axis.

The good axial alignment of the nanowire devices was exploited to calibrate the strain sensitivity of each of elements with the 3D hybrid structure allows straightforward calibration of the device sensitivity in pure tensile strain field. Application of a 10% tensile strain along the cylinder axis (FIG. 10A) yielded decreases in conductance up to 200 nS for the individual devices, d1 to d11. Because the conductance immediately returned to baseline when strain was released and under compressive loads the conductance change had the opposite sign, it can be concluded that these changes do reflect strain transferred to the nanowire sensors. From the specific response of the devices within the hybrid structure, a calibrated conductance change/1% strain value for each of the eleven sensor elements could be calculated and assigned (FIG. 10), and used for analysis of different applied strains. For example, a bending strain could be applied to the cylinder and the recorded conductance changes and calibration values could be used to map readily the 3D strain field as shown in FIG. 5C. It was noted that the one-dimensional geometry of nanowires gave these strain sensors nearly perfect directional selectivity, and thus, by developing macroporous nanoelectronic network with nanowires device aligned parallel and perpendicular to the cylinder axis allowed mapping all three components of the strain field.

FIG. 5 shows various 3D macroporous strain sensors embedded in an elastomer. FIG. 5A shows X-ray micro-computed tomography 3D reconstruction of the macroporous strain sensor array embedded in a piece of elastomer, showing both metal and elastomer. FIG. 5B shows a dark field microscopy image of a typical nanowire device indicated by the dashed circle in FIG. 5A. All of the functional nanowires were intentionally aligned parallel to the axial axis of the elastomer cylinder in this example. The white arrow points a nanowire. FIG. 5C shows that a bending strain field was applied to the elastomer piece. The 3D strain field was mapped by the nanowire strain sensors using the sensitivity calibration of the nanowire devices. The detected strains were labeled in the cylinder image at the device positions.

Free-standing three-layer interconnect ribbon fabrication and mechanical testing. A Ni sacrificial layer was defined on a SiO₂/Si substrate (600 nm SiO₂, n-type silicon 0.005 V cm, Nova Electronic Materials, Flower Mound, Tex.) by EBL and thermal deposition. SU-8/metal/SU-8 elements with 100 micrometer long and 5 micrometer wide segments over the Ni-layer and wider segments directly on substrate were defined by EBL using the same approach described herein. In brief, a 500 nm thick SU-8 layer was deposited by spin coating and defined by EBL to serve as the bottom SU-8 layer. Then EBL, thermal deposition and lift-off were used to define an asymmetrical metal layer of a 3 micrometer wide Cr/Pd/Cr (1.5/80/50 nm) ribbon centered on the bottom SU-8 element. Last, the top 500 nm thick SU-8 layer of the SU-8/metal/SU-8 elements were defined, and then the Ni sacrificial layer was removed by Ni etchant, where the final drying step was carried out by critical point drying (Autosamdri 815 Series A, Tousimis, Rockville, Md.). A schematic and an optical image of the resulting sample element are shown in FIGS. 7A and 7B, respectively. An atomic force microscope (AFM, MFP 3D, Asylum Corp.) was used to measure force versus displacement curves for the SU-8/metal/SU-8 elements (FIG. 7A). The tip of the AFM was placed at the free end of the ribbon element and then the applied force and displacement were recorded while the AFM tip was translated down (loading) and then up (unloading), with a typical data shown in FIG. 7C. The spring constant of the AFM cantilever/tip assemblies used in the measurements were calibrated by measuring the thermal vibration spectrum.

FIG. 7 shows various bending stiffness measurements. FIG. 7A is a schematic illustrating the measurement of the bending stiffness of a representative SU-8/metal/SU-8 element in the macroporous nanoelectronic networks. EBL was used to define substrate-fixed and substrate free beams, where internal stress in the central metal layer causes the structure to bend-up upon relief from the substrate. The tip of the AFM was placed at the free end of the ribbon, and then translated vertically downward (loading) and upward (unloading) to yield the force-displacement curves. In this scheme, w: the width of the ribbon, l₀: the length of the ribbon, l: the projected length of the ribbon, and d: the displacement of the AFM tip. FIG. 7B is an optical micrograph of the fabricated structural element, where the substrate fixed portion is highlighted by the dashed rectangle and the free beam is in the upper portion of the image with a width of 5 micrometers and a length of 100 micrometers. FIG. 7C shows a typical force-displacement curve with F/d for loading and unloading of 12 and 10.5 nN/μm, respectively. Similar deviation between the loading and unloading has been attributed to inelastic deformation; hence, the larger loading value was used in calculations to provide an upper limit.

Bending stiffness analysis. Due to the residual stress, the SU-8/metal/SU-8 elements bent upward from the substrate (due to internal stress of the asymmetric metal layers) with a constant curvature, K₀, and projected length, l, where l₀ is the free length defined by fabrication. A curvilinear coordinate, s, was used to describe the distance along the curved ribbon from the fixed end, and the coordinate, x, to describe the projection position of each material point of the ribbon (FIG. 8A). For a specific material point with distance s, the projection position x could be calculated as x=∫ cos ψds, where ψ=K₀s is the angle between the tangential direction of the curvilinear coordinate s and the horizontal direction (FIG. 8B). Integration yields x=sin(K₀s)/K₀ and when x=l and s=l₀, K₀=0.0128 μm⁻¹ for typical experimental parameters l₀=100 μm and l=75 μm.

As the element is deflected a distance, d, by the AFM tip with a force, F, each material point was rotated by an angle, φ, (FIG. 8B), where the anti-clockwise direction is defined as positive. Assuming a linear constitutive relation between the moment M and curvature change dφ/ds yields:

$$\frac{d ϕ}{d s} = \frac{M}{{wD}_{m}} \qquad ( 2 )$$

where M is the moment as a function of position, x (FIG. 8), and w is the width.

M(x)=−F(l−x) (3)

Solving for the bending stiffness, Dₘ, with the assumption that φ is small so that sin φ≈φ yields:

$${D}_{m} = \frac{F}{wd} ( \frac{{ll}_{0} sin ( {K}_{0} {l}_{0} )}{{K}_{0}} + \frac{1}{{K}_{0}^{2}} ( l cos ( {K}_{0} {l}_{0} ) - l + \frac{{l}_{0}}{2} ) + \frac{1}{{K}_{0}^{3}} ( \frac{sin ( 2 {K}_{0} {l}_{0} )}{4} - sin ( {K}_{0} {l}_{0} ) ) ) \qquad ( 4 )$$

The slope of a representative loading force-deflection curve, yields F/d=12nN/μm (FIG. 7C), and using equation 4, the calculated bending stiffness per width (w=5 micrometers) was Dₘ=0.358 nN·m. For typical 3D macroporous nanoelectronic networks the area fraction for both types of elements (i.e., SU-8 and SU-8/metal/SU-8) could range from 1 to 10%, yielding values of the effective bending stiffness from 0.0038 to 0.0378 nN·m.

FIG. 8 shows schematics for these calculations. FIG. 8A shows a schematic of the position of the substrate free beam before (upper) and after (lower) applying a calibrated force, F, and vertical displacement, d, at the end of the beam with the AFM. FIG. 8B shows the angle between the tangential direction of a material point on the beam and the horizontal direction, ψ, of the ribbon before (upper) and after displacement, ψ+φ, (lower). l₀: the total length of the ribbon. l: projection of the ribbon.

Accordingly, these examples demonstrate a general strategy for preparing ordered 3D interconnected and addressable macroporous nanoelectronic networks from ordered 2D nanowire nanoelectronic “precursors,” which are fabricated by conventional lithography. The 3D networks had porosities larger than 99%, contain hundreds of addressable nanowire devices, and had feature sizes from the 10 micron scale for electrical and structural interconnections to the 10 nanometer scale for the functional nanowire device elements. The macroporous nanoelectronic networks were merged with organic gels and polymers to form hybrid materials in which the basic physical and chemical properties of the host were not substantially altered, and electrical measurements further showed >90% yield of active devices in the hybrid materials. Further demonstrated was a new approach to determine the positions of the nanowire devices within 3D hybrid materials with about 14 nm resolution that involved simultaneous nanowire device photocurrent/confocal microscopy imaging measurements. This method also could have substantial impact on localizing device positions in macroporous nanoelectronic/biological samples, where it may provide the capability of determining positions of sensory devices at the subcellular level.

In addition, functional properties of these hybrid materials were explored. First, it was shown that it was possible to map time-dependent pH changes throughout a nanowire network/agarose gel sample during external solution pH changes. These results suggest that the 3D macroporous nanoelectronic networks could be used for real-time mapping of diffusion of chemical and biological species through polymeric samples as well as biological materials such as synthetic tissue. Second, it was demonstrated that Si nanowire elements could function as strain sensors, and thereby characterize the strain field in a hybrid nanoelectronic elastomer structures subject to uniaxial and bending forces. More generally, this approach to fabrication of multi-functional 3D electronics and integration with host materials can be used for general fabrication of truly 3D integrated circuits based on conventional fabrication processes via assembly from a 2D precursor structure, and seamless 3D incorporation of multi-functional nanoelectronics into living and nonliving systems.

### Example 6

This example describes various methods used in the above examples.

Nanowire synthesis. Single-crystalline nanowires were synthesized using the Au nanocluster-catalyzed vapor-liquid-solid growth mechanism in a home-built chemical vapor deposition (CVD) system. Au nanoclusters (Ted Pella Inc., Redding, Calif.) with 30 nm diameters were dispersed on the oxide surface of silicon/SiO₂ substrates (600 nm oxide) and placed in the central region of a quartz tube CVD reactor system. Uniform 30 nm p-type silicon nanowires were synthesized using reported methods. In a typical synthesis, the total pressure was 40 torr and the flow rates of SiH₄, diborane (B₂H₆, 100 p.p.m. in H₂), and hydrogen (H₂, Semiconductor Grade), were 2, 2.5 and 60 standard cubic centimeters per minute (SCCM), respectively. The silicon-boron feed-in ratio was 4000:1, and the total nanowire growth time was 30 min.

3D macroporous nanoelectronic networks. The 3D macroporous nanowire nanoelectronic networks was initially fabricated on the oxide or nitride surfaces of silicon substrates (600 nm SiO₂ or 100 SiO₂/200 Si₃N₄, n-type 0.005 V cm, Nova Electronic Materials, Flower Mound, Tex.) prior to relief from the substrate. Steps used in the fabrication of the 3D macroporous nanowire nanoelectronic networks were as follows: (i) lithography and thermal deposition were used to pattern a 100 nm nickel metal layer, where the nickel served as the final relief layer for the 2D free-standing macroporous nanowire nanoelectronic networks. (ii) a 300-500 nm layer of SU-8 photoresist (2000.5, MicroChem Corp., Newton, Mass.) was deposited over the entire chip followed by pre-baking at 65° C. and 95° C. for 2 and 4 min, respectively, then (iii) the synthesized nanowires were directly printed from growth wafer over the SU-8 layer by contact printing methods. (iv) Lithography (photolithography or electron beam lithography) was used to define regular patterns on the SU-8. After post-baking (65° C. and 95° C. for 2 and 4 min, respectively), SU-8 developer (MicroChem Corp., Newton, Mass.) was used to develop the SU-8 pattern. Those areas exposed to UV light or electron beam became dissolvable to SU-8 developer and other areas were dissolved by SU-8 developer. Those nanowires on the non-exposed area were removed by further washing away in isopropanol solution (30 s) for twice leaving those selected nanowires on the regular pattern SU-8 structure. The SU-8 patterns were cured at 180° C. for 20 min. (v) A 300-500 nm layer of SU-8 photoresist was deposited over the entire chip followed by pre-baking at 65° C. and 95° C. for 2 and 4 min, respectively. Then, lithography was used to pattern the bottom SU-8 layer for passivating and supporting the whole device structure. The structure was post-baked, developed and cured by the same procedure as described above.

(vi) Lithography and thermal deposition were used to define and deposit the metal contact to address each nanowire device and form interconnections to the input/output pads for the array. For the mesh device, in which the metal is non-stressed, symmetrical Cr/Pd/Cr (1.5/50-80/1.5 nm) metal was sequentially deposited followed by metal lift-off in acetone. For the self-organized networks, in which the metal are stressed, nonsymmetrical Cr/Pd/Cr (1.5/50-80/50-80 nm) metal was sequentially deposited followed by metal lift-off in acetone. (vii) A 300-500 nm layer of SU-8 photoresist was deposited over the entire chip followed by pre-baking at 65° C. and 95° C. for 2 and 4 min, respectively. Then, lithography was used to pattern the top SU-8 layer for passivating the whole device structure. The structure was post-baked, developed and cured by the same procedure as described above. (viii) The 2D macroporous nanowire nanoelectronic networks was released from the substrate by etching of the nickel layer (Nickel Etchant TFB, Transene Company Inc., Danvers, Mass.) for 60-120 min at 25° C. (ix) The 3D macroporous nanowire nanoelectronic networks were dried by a critical point dryer (Autosamdri 815 Series A, Tousimis, Rockville, Md.) and stored in the dry state prior to use.

Characterization of macroporous nanoelectronic networks Scanning electron microscopy (SEM, Zeiss Ultra55/Supra55VP field-emission SEMs) was used to characterize the macroporous nanoelectronic networks. Bright-field and dark-field optical micrographs of samples were acquired on an Olympus FSX100 system using FSX-BSW software (ver. 02.02). Fluorescence images of the 3D macroporous nanoelectronic networks were obtained by doping the SU-8 resist solution with Rhodamine 6G (Sigma-Aldrich Corp., St. Louis, Mo.) at a concentration less than 1 microgram/mL before deposition and patterning. ImageJ (ver. 1.45i, Wayne Rasband, National Institutes of Health, USA) was used for 3D reconstruction and analysis of the confocal and epi-fluorescence images. Bending stiffness of the SU-8/metal/SU-8 ribbon was measured using an Asylum MFP-3D AFM system. An AFM tip with calibrated k of 9.7 nN/nm is used.

Electrical measurement of 3D macroporous nanoelectronic networks. NW device recording was carried out with a 100 mV DC source voltage, and the current was amplified with a home-built multi-channel current/voltage preamplifier with a typical gain of 10⁶ A/V. The signals were filtered through a home-built conditioner with band-pass of 0-3 kHz, digitized at a sampling rate of 20 kHz (Axon Digi1440A) and recorded using Clampex 10 software (MDS).

3D macroporous photodetectors and device localization in 3D. Confocal laser scanning microscopy (Fluoview FV1000, Olympus America Inc., PA) was used to characterize the 3D macroporous nanoelectronic network. Conventional 405 nm and 473 nm wavelength lasers, where 405 nm was used to produce photocurrents in the nanowire transistor devices, and the 473 nm was used for fluorescence imaging. The SU-8 structure was doped with Rodamine 6G for fluorescence imaging. The macroporous nanoelectronic network was immersed into dioniozed (DI) water, individual devices were biased with 100 mV, and 40× or 100× water immersion objectives were used for imaging. The photocurrent signal was amplified (SIM 918, Stanford Research System, MA) bandpass filtered, (1-6000 Hz, home-built system), and synchronized with laser scanning position using an analog signal input box (F10ANALOG, Olympus America Inc., PA). The conductance signal from the resulting images was read out by imageJ, and the data were analyzed and fitted by OriginPro.

3D macroporous chemical sensors. Agarose (Sigma) was dissolved into DI water and made as 0.5%, and heated up to 100° C. The gel was drop casted onto the device and cooled down to room temperature. 4′,6-diamidino-2-phenylindole (DAPI, Sigma) was used to dope the gel for the confocal 3D reconstructed imaging. A PDMS (polydimethylsiloxane) fluidic chamber with input/output tubing and Ag/AgCl electrodes was sealed with the silicon substrate and the device or device-gel hybrid using silicone elastomer glue (Kwik-Sil, World Precision Instruments, Inc). Fresh medium was delivered to the device region through both inner and outer tubing. The solution pH was stepwise varied inside the channel by flowing (20 mL/h) lx phosphate buffered solutions with fixed pH values from pH 6-8. The recorded device signals were filtered with a bandpass filter of 0-300 Hz.

3D macroporous strain sensors in elastomer. A freestanding 2D macroporous nanoelectronic network was suspended in water, and placed on a thin (200 to 500 micrometer) piece of cured silicone elastomer sheet (Sylgard 184, Dow Corning). The hybrid macroporous nanowire network/silicon elastomer was rolled into a cylinder, infiltrated with uncured silicone elastomer under vacuum, and cured at 70° C. for 4 hours. The resulting hybrid nanoelectronic/elastomer cylinders had volumes of about 300 mm³ with volume ratio of device/elastomer of <0.1%. The structure of the macroporous electronics/elastomer hybrid was determined using a HMXST X-ray micro-CT system with a standard horizontal imaging axis cabinet (model: HMXST225, Nikon Metrology, Inc., Brighton, Mich.). In a typical imaging experiment, the acceleration voltage was 60-70 kV, the electron beam current was 130-150 mA, and no filter was used. BGStudio MAX (ver. 2.0, Volume Graphics GMbh, Germany) was used for 3D reconstruction and analysis of the micro-CT images, which resolve the 3D metal interconnect structure and nanowire S/D contacts; the Si nanowires were not resolved in these images but were localized at the scale of the S/D contacts. The piezoelectric response to strain of the nanowire devices was calibrated using a mechanical clamp device under tensile strain (FIG. 10), where the strain was calculated from the length change of the cylindrical hybrid structure. The bending strain field was determined in experiments where the the cylindrical hybrid structure, with calibrated nanowire strain sensors, was subject to random bending deflections.

FIG. 10 shows the calibration of the 3D macroporous nanoelectronic strain sensors. FIG. 10A shows conductance change versus time as a 10% tensile strain was applied to hybrid 3D macroporous nanoelectronic networks/PDMS cylindrical sample. The downward and upward pointing arrows denote the times when the strain was applied and released, respectively. The direction of strain on the cylindrical hybrid sample and projected position of the macroporous nanoelectronic networks are indicated in the right optical micrograph. The conductance changes of 11 measured nanowire devices (labeled arbitrarily in terms of increasing sensitivity) were recorded and used for the conductance change per strain calibration. FIG. 10B shows strain sensitivity calibration of the nanowire devices is plotted in 3D. The data points are coded by the sensitivity of the devices.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. An article, comprising:
an inorganic material comprising a three-dimensional structure comprising nanoscale wires.

2. The article of claim 1, wherein the inorganic material comprises a metal.

3. An article, comprising:
a polymer comprising a three-dimensional structure comprising nanoscale wires, wherein the polymer comprises non-naturally occurring monomers.

4. The article of claim 3, wherein the polymer comprises polydimethylsiloxane.

5. An article, comprising:
a fabric comprising a three-dimensional structure comprising nanoscale wires, wherein the polymer comprises non-naturally occurring monomers.

6. An article, comprising:
rubber comprising a three-dimensional structure comprising nanoscale wires, wherein the polymer comprises non-naturally occurring monomers.

7. An article, comprising:
a fluidic channel, wherein at least a portion of a wall of the fluidic channel comprises a three-dimensional structure comprising nanoscale wires.

8. The article of any one of claims 1-7, wherein the three-dimensional structure defines an electrical network.

9. The article of any one of claims 1-8, wherein at least a portion of the three-dimensional structure is embedded within the article.

10. The article of any one of claims 1-9, wherein at least a portion of the three-dimensional structure is substantially fully embedded within the article.

11. The article of any one of claims 1-10, wherein at least 50% of the nanoscale wires within the article form portions of one or more electrical circuits connectable to an electrical circuit that extends externally of the article.

12. The article of any one of claims 1-11, wherein at least some of the nanoscale wires are connectable to an electrical circuit that extends externally of the article.

13. The article of claim 12, wherein the electrical circuit is in electrical communication with a computer.

14. The article of any one of claims 1-13, wherein the three-dimensional structure comprises an electrical network comprising at least some of the nanoscale wires.

15. The article of any one of claims 1-14, wherein the three-dimensional structure is formed from a curled and/or folded two-dimensional structure.

16. The article of claim 15, wherein the two-dimensional structure is curled into a cylinder having a maximum diameter of no more than about 5 mm to form the three-dimensional structure.

17. The article of any one of claim 15 or 16, wherein the two-dimensional structure is curled into a cylinder having a maximum diameter of no more than about 2 mm to form the three-dimensional structure.

18. The article of any one of claims 1-17, wherein the three-dimensional structure has an average pore size of between about 100 micrometers and about 1.5 mm

19. The article of any one of claims 1-18, wherein the three-dimensional structure has a free volume of at least about 50%.

20. The article of any one of claims 1-19, wherein the three-dimensional structure has an areal mass density of less than about 60 micrograms/cm².

21. The article of any one of claims 1-20, wherein the three-dimensional structure has an average pore size of at least about 100 micrometers.

22. The article of any one of claims 1-21, wherein the three-dimensional structure has an average pore size of no more than about 1.5 mm.

23. The article of any one of claims 1-22, wherein the three-dimensional structure has a bending stiffness of less than about 3 nN m.

24. The article of any one of claims 1-23, wherein at least one of the nanoscale wires is a semiconductor nanowire.

25. The article of any one of claims 1-24, wherein at least one of the nanoscale wires comprises silicon.

26. The article of any one of claims 1-25, wherein at least one of the nanoscale wires is a p-type semiconductor nanowire.

27. The article of any one of claims 1-26, wherein at least one of the nanoscale wires is an n-type semiconductor nanowire.

28. The article of any one of claims 1-27, wherein at least some of nanoscale wires form part of a field effect transistor.

29. The article of any one of claims 1-28, wherein at least one of the nanoscale wires is a kinked nanoscale wire.

30. The article of any one of claims 1-29, wherein at least one of the nanoscale wires has a diameter of less than about 1 micrometer.

31. The article of any one of claims 1-30, wherein the nanoscale wires have a variation in average diameter of less than about 20%.

32. The article of any one of claims 1-31, wherein at least one of the nanoscale wires is pH-sensitive.

33. The article of any one of claims 1-32, wherein at least one of the nanoscale wires has a conductance of at least about 1 microsiemens.

34. The article of any one of claims 1-33, wherein at least one of the nanoscale wires is responsive to a mechanical property external to the nanoscale wire.

35. The article of any one of claims 1-34, wherein at least one of the nanoscale wires is responsive to an electrical property external to the nanoscale wire.

36. The article of any one of claims 1-35, wherein the at least one nanoscale wire exhibits a voltage sensitivity of at least about 5 microsiemens/V.

37. The article of any one of claims 1-36, wherein the three-dimensional structure comprises at least about 10 nanoscale wires.

38. The article of any one of claims 1-37, wherein the three-dimensional structure has a density of nanoscale wires of at least about 30 nanoscale wires/mm³.

39. The article of any one of claims 1-38, wherein the nanoscale wires exhibit an average separation, between a nanoscale wire and its nearest nanoscale wire, of less than about 1 mm.

40. The article of any one of claims 1-39, wherein at least about 50% of the nanoscale wires within the three-dimensional structure are individually electronically addressable.

41. The article of any one of claims 1-40, wherein the three-dimensional structure comprises a metal lead in electrical communication with at least one of the nanoscale wires.

42. The article of claim 41, wherein the metal lead forms a portion of an electrical circuit that extends externally of the article.

43. The article of any one of claim 41 or 42, wherein the metal lead is in electrical communication with at least one of the nanoscale wires.

44. The article of any one of claims 41-43, wherein the metal lead comprises chromium.

45. The article of any one of claims 41-44, wherein the metal lead comprises palladium.

46. The article of any one of claims 41-45, wherein the metal lead has a maximum cross-sectional dimension of less than about 5 micrometers.

47. An article, comprising:
a fluidic channel, wherein at least a portion of a wall of the fluidic channel comprises a curled two-dimensional electrical network comprising nanoscale wires.

48. The article of claim 47, wherein the channel is a microfluidic channel.

49. The article of any one of claim 47 or 48, wherein the fluidic channel is defined within a polymer.

50. The article of claim 49, wherein the polymer comprises polydimethylsiloxane.

51. An article, comprising:
a fluidic channel, wherein at least a portion of a wall of the channel comprises a three-dimensional structure having an average pore size of between about 100 micrometers and about 1.5 mm.

52. The article of claim 51, wherein the channel is a microfluidic channel.

53. An article, comprising:
a fabric comprising nanoscale wires, wherein at least some of the nanoscale wires are connectable to an electrical circuit that extends externally of the fabric.

54. The article of claim 53, wherein the fabric forms part of an article of clothing.

55. The article of claim 53, wherein the fabric comprises one or more of wool, silk, cotton, aramid, acrylic, nylon, spandex, rayon, or polyester.

56. An article, comprising:
rubber comprising nanoscale wires, wherein at least some of the nanoscale wires are connectable to an electrical circuit that extends externally of the rubber.

57. The article of claim 56, wherein the article is an article of footwear.

58. An article defining a microfluidic system and comprising nanoscale wires, wherein at least some of the nanoscale wires are connectable to an electrical circuit that extends externally of the article.

59. A method, comprising:
determining a chemical, mechanical, and/or electrical property of an inorganic material at a resolution of at least 1 mm using sensors disposed internally of the inorganic material.

60. A method, comprising:
determining a chemical, mechanical, and/or electrical property of a rubber at a resolution of at least 1 mm using sensors disposed internally of the rubber.

61. A method, comprising:
determining a chemical, mechanical, and/or electrical property of a fabric at a resolution of at least 1 mm using sensors disposed internally of the fabric.

62. A method, comprising:
determining a chemical, mechanical, and/or electrical property of a polymeric material at a resolution of less than 1 mm using sensors disposed internally of the polymeric material, wherein the polymeric material comprises non-naturally occurring monomers.

63. The method of any one of claims 59-62, wherein the property is a chemical property.

64. The method of any one of claims 59-62, wherein the property is pH.

65. The method of any one of claims 59-62, wherein the property is a mechanical property.

66. The method of any one of claims 59-62, wherein the property is strain.

67. The method of any one of claims 59-62, wherein the property is an electrical property.

68. The method of any one of claims 59-67, wherein the resolution is less than about 100 micrometers.

69. The method of any one of claims 59-68, wherein the sensors comprise one or more nanoscale wires.

70. The method of claim 70, comprising determining a chemical, mechanical, and/or electrical property of the one or more nanoscale wires.

71. The method of any one of claim 70 or 71, comprising individually determining a chemical, mechanical, and/or electrical property of only one nanoscale wire.

72. A method, comprising:
determining mechanical strain of a material by determining electrical properties of nanoscale wires contained within a three-dimensional network within the material.
